(19) United States
(12) Patent Application Publication
(10) Pub. No.: US 2026/0155168 A1
(43) Pub. Date: Jun. 4, 2026

(54) APPARATUS INCLUDING READ-WRITE DATA BUS BUFFER

(71) Applicant: MICRON TECHNOLOGY, INC., BOISE, ID (US)

(72) Inventors: Akeno Ito, Yokohama (JP); Yuki Miura, Sagamihara (JP); Atsushi Shimizu, Osaka (JP)

(21) Appl. No.: 19/401,220

(22) Filed: Nov. 25, 2025

Related U.S. Application Data
(60) Provisional application No. 63/728,139, filed on Dec. 4, 2024.

(51) Int. Cl. G11C 11/4093; G11C 11/4091; G11C 11/4096

(52) U.S. Cl. CPC G11C 11/4093; G11C 11/4091; G11C 11/4096

(57) ABSTRACT

Some embodiments of the disclosure provide an apparatus comprising a data terminal, a first buffer coupled to the data terminal, and a second buffer coupled to the first buffer. The first buffer includes an even buffer and an odd buffer coupled to the data terminal via an even data bus and an odd data bus, respectively. The second buffer is coupled to the even buffer and the odd buffer of the first buffer via an even global data bus and an odd global data bus, respectively, and consolidates the even global data bus and the odd global bus into a single global data bus.

### CROSS-REFERENCE TO RELATED APPLICATIONS

This application claims the filing benefit of U.S. Provisional Application No. 63/728,139, filed December 4, 2024. This application is incorporated by reference herein in its entirety and for all purposes.

### BACKGROUND

High data reliability, high speed of memory access, low power consumption, and reduced chip size are some features that are demanded from semiconductor memory devices, such as a dynamic random-access memory (DRAM). Memory devices may include data terminals for data input and output. Memory devices may also include data bus and data buffers coupled to the data terminals.

### BRIEF DESCRIPTION OF THE DRAWINGS

FIG. 1 is a block diagram of an example apparatus according to some embodiments of the disclosure.

FIG. 2 is a block diagram of at least part of an example apparatus according to some embodiments of the disclosure.

FIG. 3 is a block diagram of at least part of an example data terminal DQ and global data bus-data bus buffer GDBuff configuration according to some embodiments of the disclosure.

FIGS. 4A and 4B each depict an example layout of a set of BRWBUSIC, Even_BRWBUSI and Odd_BRWBUSI in GDBuff according to some embodiments of the disclosure.

FIGS. 5A and 5B each depict an example layout of a set of BRWBUSIC, Even_BRWBUSI and Odd_BRWBUSI in GDBuff according to some embodiments of the disclosure.

FIGS. 6A and 6B each depict an example arrangement of power supply wirings according to some embodiments of the disclosure.

FIGS. 7A and 7B each depict an example arrangement of control circuits and signal lines according to some embodiments of the disclosure.

FIG. 8 depicts an example layout of a set of BRWBUSIC, Even_BRWBUSI and Odd_BRWBUSI in GDBuff according to some embodiments of the disclosure.

FIGS. 9 and 10 each are a schematic diagram of at least part of an example buffer circuit according to some embodiments of the disclosure.

### DETAILED DESCRIPTION

Various example embodiments of the disclosure will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, some of the same signs may be omitted for the same or substantially the same elements for ease of illustration. In the drawings, the dimensions and dimensional ratios of each unit do not necessarily match the actual dimensions and dimensional ratios in the embodiments.

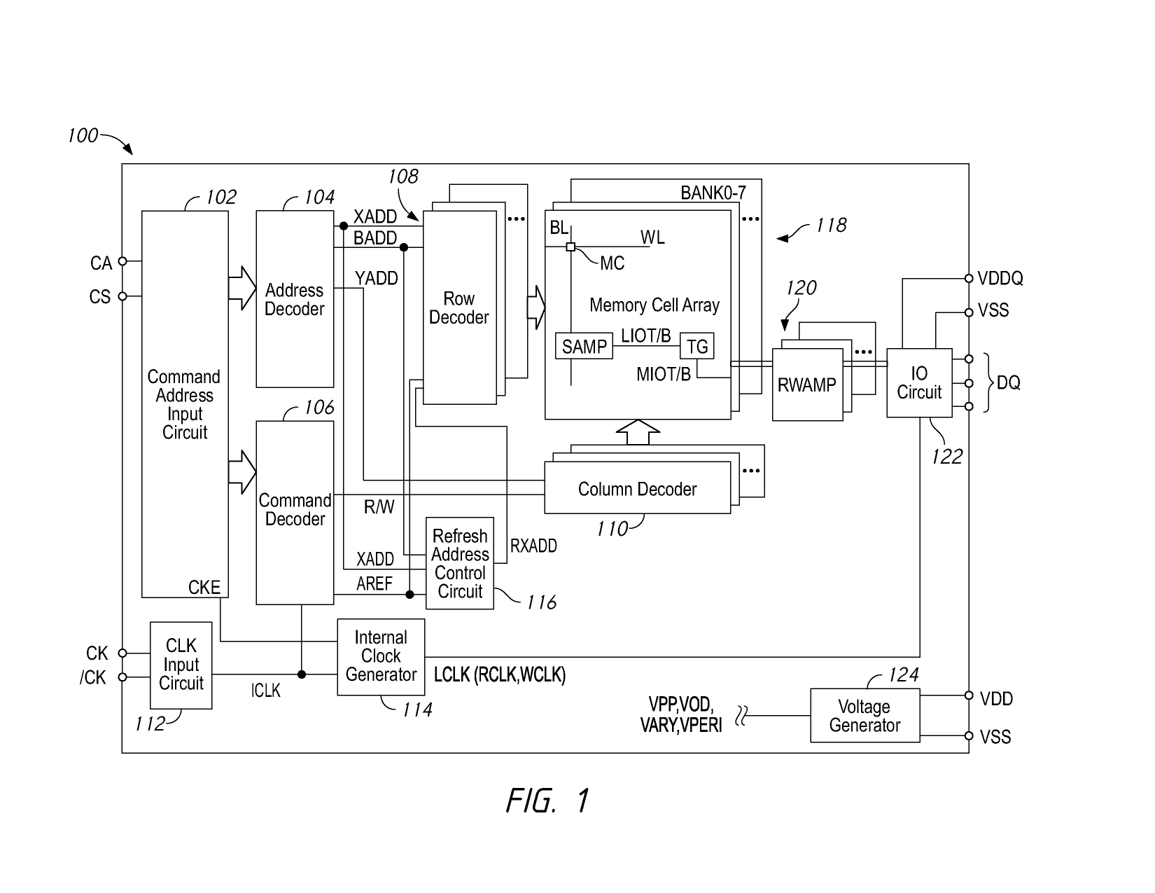

FIG. 1 is a block diagram of an example apparatus 100 according to some embodiments of the disclosure. The apparatus 100 may be a semiconductor memory device, such as a dynamic random-access memory (DRAM). The apparatus 100 includes a memory array 118. The memory array 118 is shown as including a plurality of memory banks. In the embodiment of FIG. 1, the memory array 118 is shown as including eight memory banks BANK0-BANK7. More or fewer banks may be included in the memory array 118 of other embodiments. Each memory bank includes a plurality of word lines WL, a plurality of bit lines (may also be referred to as digit lines) BL, and a plurality of memory cells MC arranged at intersections of the plurality of word lines WL and the plurality of bit line BL. Selection of the word line WL is performed by a row decoder 108 and selection of the bit lines BL is performed by a column decoder 110. In the embodiment of FIG. 1, the row decoder 108 includes a respective row decoder for each memory bank and the column decoder 110 includes a respective column decoder for each memory bank. The bit lines BL are coupled to a respective sense amplifier SAMP of the memory array 118. Read data from the bit line BL is amplified by the sense amplifier SAMP and transferred to read/write amplifiers (RWAMPs) 120 over complementary local data lines LIOT/B, transfer gate TG, and complementary main data lines MIOT/B which are coupled to RWAMP 120. Conversely, write data outputted from RWAMP 120 is transferred to the sense amplifier SAMP over the complementary main data lines MIOT/B, the transfer gate TG, and the complementary local data lines LIOT/B, and written in the memory cell MC coupled to the bit line BL.

The apparatus 100 may employ a plurality of external terminals that include command and address (CA) terminals coupled to a command and address bus to receive commands and addresses and a chip select (CS) signal, clock terminals to receive clocks CK and /CK, data terminals DQ to provide data, and power supply terminals to receive power supply potentials VDD, VSS, and VDDQ.

The clock terminals are supplied with external clocks CK and /CK that are provided to an input circuit 112. The external clocks CK and /CK may be complementary. The input circuit 112 generates an internal clock ICLK based on the CK and /CK clocks. The ICLK clock is provided to the command decoder 106 and to an internal clock generator 114. The internal clock generator 114 provides various internal clocks LCLK based on the ICLK clock. The LCLK clocks may be used for timing operation of various internal circuits. The internal clocks LCLK are provided to an input and output (IO) circuit 122 to time operation of circuits included in the IO circuit 122, for example, to data receivers to time the receipt of write data.

The internal clocks LCLK may include a read clock RCLK which is used to control the timing of read operations and a write clock WCLK which is used to control the timing of write operations. The internal clocks may be passed to the IO circuit 122. In some instances, the internal clocks may also be passed to internal components, such as RWAMP 120.

The CA terminals may be supplied with memory addresses. The memory addresses supplied to the CA terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The CA terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to the command decoder 106 via the command/address input circuit 102. The command decoder 106 includes circuits to decode the internal command signals to generate various internal signals and commands for performing operations. For example, the command decoder 106 may provide a row command signal to select a word line and a column command signal to select a bit line.

The apparatus 100 may receive an access command which is a read command. When a read command is received, and a bank address, a row address and a column address are timely supplied with an activate command and the read command, read data is read from memory cells in the memory array 118 corresponding to the row address and column address. The read command is received by the command decoder 106, which provides internal commands so that the read data from the memory cells in the memory array 118 is provided to RWAMP 120. The read data is output to outside the apparatus 100 from the data terminals DQ via the IO circuit 122.

The apparatus 100 may receive an access command which is a write command. When the write command is received, and a bank address, a row address and a column address are timely supplied with an activate command and the write command, write data is supplied through the DQ terminals to RWAMP 120. The write data supplied to the data terminals DQ is written to the memory cells in the memory array 118 corresponding to the row address and column address. The write command is received by the command decoder 106, which provides internal commands so that the write data is received by data receivers in the IO circuit 122. Write clocks may also be provided to the external clock terminals for timing the receipt of the write data by the data receivers of the IO circuit 122. The write data is supplied via the IO circuit 122 to RWAMP 120.

The apparatus 100 may also receive commands causing it to carry out one or more refresh operations as part of a self-refresh mode. In some embodiments, the self-refresh mode command may be externally issued to the apparatus 100. In some embodiments, the self-refresh mode command may be periodically generated by a component of the device. In some embodiments, when an external signal indicates a self-refresh entry command, the refresh signal AREF may also be activated.

The power supply terminals are supplied with power supply potentials VDD and VSS. The power supply potentials VDD and VSS are supplied to an internal voltage generator circuit 124. The internal voltage generator circuit 124 generates various internal potentials such as VPP, VOD, VARY, VPERI, and the like based on the power supply potentials VDD and VSS.

The power supply terminals are also supplied with power supply potential VDDQ. The power supply potential VDDQ is supplied to the IO circuit 122. The power supply potential VDDQ may be the same potential as the power supply potential VDD in an embodiment of the disclosure. The power supply potential VDDQ may be a different potential from the power supply potential VDD in another embodiment of the disclosure. The power supply potential VDDQ is used for the IO circuit 122 so that power supply noise generated by the IO circuit 122 does not propagate to the other circuit blocks.

In some embodiments of the disclosure, the plurality of memory cells MC form a memory cell array in each memory bank of the memory array 118. The memory cell array may include a plurality of memory mats (not separately depicted). The memory cell array may be divided into a plurality of memory mats. Each memory mat has a group of word lines WL and bit lines BL assigned thereto. In the assigned group, an array of the word lines WL extends in one direction, and an array of the bit lines BL extends in another direction. Each line extends through the memory mat to an outside area of the memory mat. In the outside area of the memory mat, word line drivers may be coupled to the word lines WL, and sense amplifiers may be coupled to the bit lines BL. The memory mat may also be referred to as a memory array mat.

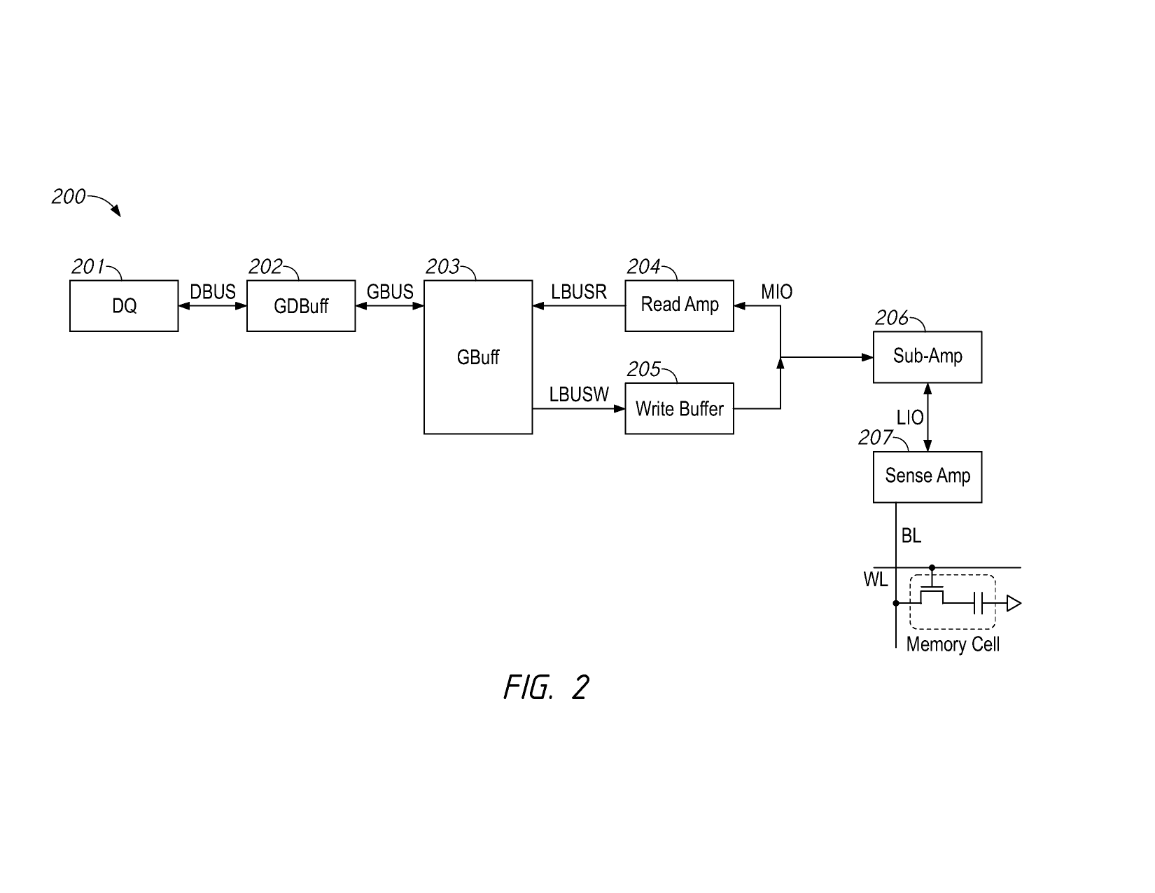

FIG. 2 is a block diagram of at least part of an example apparatus 200 according to some embodiments of the disclosure. The example apparatus 200 includes a data terminal (hereinafter referred to as DQ) 201, a global data bus-data bus buffer (hereinafter referred to as GDBuff) 202, a global data bus buffer (hereinafter referred to as GBuff) 203, a read amplifier 204, and a write buffer 205, which are coupled to a sub-amplifier 206 via a main input/output data line MIO and a sense amplifier 207 via a local input/output data line LIO. The sense amplifier 207 is coupled to a memory cell 208. The memory cell 208 includes a cell capacitor and a cell transistor and is arranged at an intersection of a word line WL and a bit line (or a digit line) BL. DQ 201 is coupled to GDBuff 202 via a data bus (hereinafter referred to as DBUS). GDBuff 202 is coupled to GBuff 203 via a global data bus (hereinafter referred to as GBUS). GBuff 203 may include an error correction circuit. GBuff 203 is coupled to the read amplifier 204 via a local data bus LBUSR for a read operation and to the write buffer 205 via a local data bus LBUSW for a write operation.

In some instances, DQ 201 and the memory cell may correspond to DQ and MC in FIG. 1, respectively. The sense amplifier 207 may correspond to the sense amplifier SAMP in FIG. 1 in the outside area of the memory mat. The sub-amplifier 206 may also be provided in the outside area of the memory mat, for example, in the transfer gate TG or separately from the transfer gate TG. GDBuff 202, GBuff 203, the read amplifier 204, and the write buffer 205 may be provided between DQ and the memory cell array in FIG. 1. GDBuff 202, GBuff 203, the read amplifier 204, and the write buffer 205 may at least partially correspond to or may be separately provided from RWAMP 120 and/or the IO circuit 122 in FIG. 1. The relations between the elements in FIG. 2 and the elements in FIG. 1 are not limited to those described above.

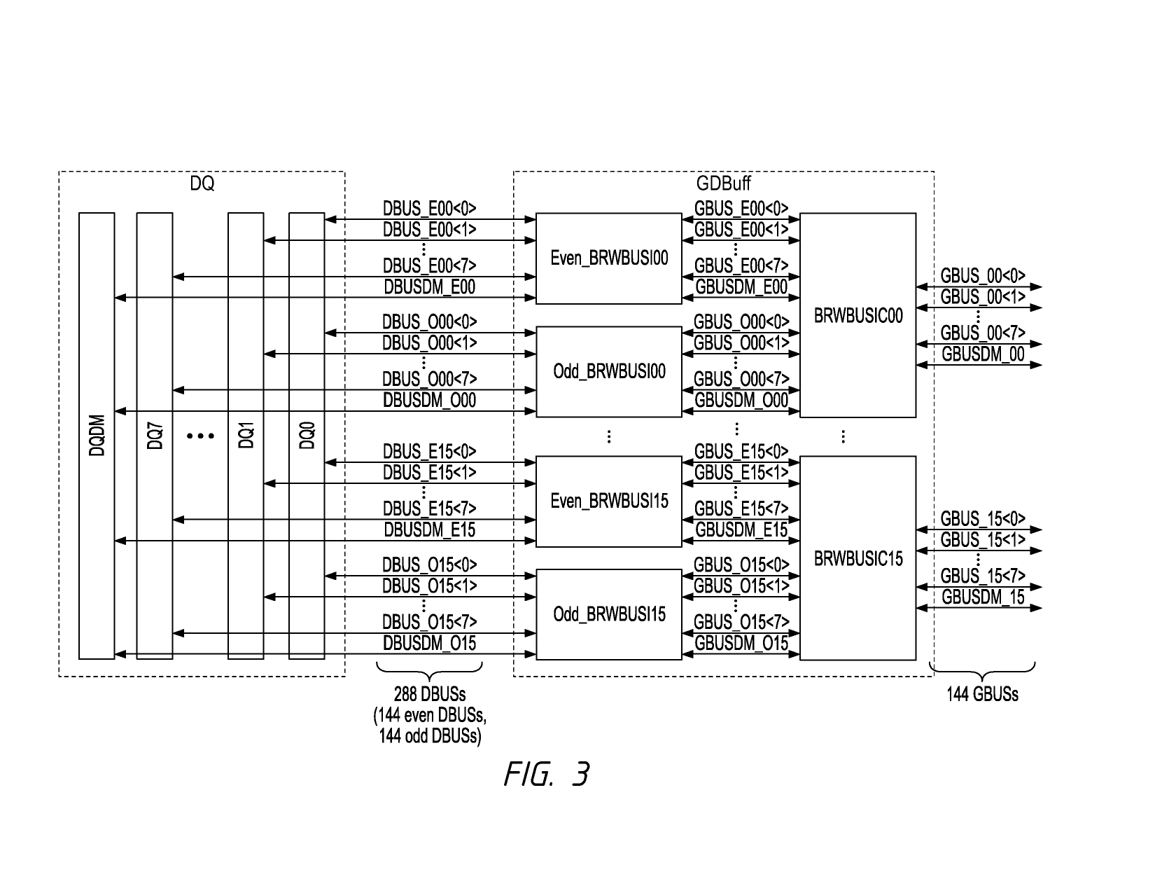

FIG. 3 is a block diagram of at least part of an example data terminal DQ and global data bus-data bus buffer GDBuff configuration according to some embodiments of the disclosure. DQ and GDBuff may correspond to, respectively, DQ 201 and GDBuff 202 in FIG. 2 which are coupled to each other via DBUS. DQ includes a plurality of data terminals DQ0-DQ7 + DQDM. The number of data terminals is not limited thereto, and may be determined based on device design, configuration, and the like. In some instances, DQ0-DQ7 may correspond to DRAM pins for data input and output, and DQDM (or simply DM) may correspond to a DRAM pin for data mask input and output. Other DQ configurations may be applicable as appropriate. In DRAM, multiple data bits are controlled to be received at or sent from DQ. The number of data bits may be 4, 8, 16 or 32, that is a power of 2. To capture or latch the data with certainty, an even data path (including even data buses and even buffers) and an odd data path (including even data buses and even buffers) may be separated. For example, if DRAM receives 8 data bits in series, 0, 2, 4 and 6 data bits go through the even data path and 1, 3, 5 and 7 data bits go through the odd data path.

DBUS has a plurality of even data buses (hereinafter referred to as DBUS_E) and a plurality of odd data buses (hereinafter referred to as DBUS_O). In the example configuration, DBUS_E includes sixteen sets, namely DBUS_E00-DBUS_E15, and DBUS_O includes sixteen sets, namely DBUS_O00-DBUS_O15, to correspond to the number of burst lengths 00-15. The number of DBUS_E sets, the number of DBUS_O sets, and the number of burst lengths are not limited thereto; they may be determined based on device design, configuration, and the like.

In the example configuration, each of DBUS_E00-DBUS_E15 includes a set of nine even data buses corresponding to DQ0-DQ7 + DQDM. For example, DBUS_E00 includes a set of DBUS_E00<0>-DBUS_E00<7> and DBUSDM_E00, and DBUS_E15 includes a set of DBUS_E15<0>-DBUS_E15<7> and DBUSDM_E15. Likewise, each of DBUS_O00-DBUS_O15 includes a set of nine odd data buses corresponding to DQ0-DQ7 and DQDM. For example, DBUS_O00 includes a set of DBUS_O00<0>-DBUS_O00<7> and DBUSDM_O00, and DBUS_O15 includes a set of DBUS_O15<0>-DBUS_O15<7> and DBUSDM_O15. In total, there are 288 DBUSs including 144 even DBUSs and 144 odd DBUSs in the example configuration.

Each of DBUS_E00-DBUS_E15 has its even data buses (e.g., DBUS_E00<0>-DBUS_E00<7> and DBUSDM_E00 or DBUS_E15<0>-DBUS_E15<7> and DBUSDM_E15) coupled to DQ0-DQ7 and DQDM at first bus ends (which are left-side bus ends in the drawing), respectively, and each of DBUS_O00-DBUS_O15 has its odd data buses (e.g., DBUS_O00<0>-DBUS_O00<7> and DBUSDM_O00 or DBUS_O15<0>-DBUS_O15<7> and DBUSDM_O15) coupled to DQ0-DQ7 and DQDM at first bus ends (which are left-side bus ends in the drawing), respectively. In other words, for example, DQ0 is coupled to DBUS_E00<0>, DBUS_E01<0>, DBUS_E02<0>, …, DBUS_E15<0> and DBUS_O00<0>, DBUS_O01<0>, DBUS_E02<0>, …, DBUS_E15<0>, and DQDM is coupled to DBUSDM_E00, DBUSDM_E01, DBUSDM_E02, …, DBUSDM_E15 and DBUSDM_O00, DBUSDM_O01, DBUSDM_E02, …, DBUSDM_E15. The number of DBUS_Es and the number of DBUS_Es as well as their arrangement with respect to DQs are not limited to the depicted example configuration; they may be determined based on device design, configuration, and the like.

DBUS_Es and DBUS_Os are coupled to GDBuff at second bus ends (which are right-side bus ends in the drawing) opposite to the first bus ends. GDBuff includes a first buffer (hereinafter referred to as BRWBUSI) for DBUS and a second buffer (hereinafter referred to as BRWBUSIC) for GBUS.

The first buffer BRWBUSI includes a plurality of first even buffers (hereinafter referred to as Even_BRWSBUSI) for DBUS_E and a plurality of first odd buffers (hereinafter referred to as Odd_ BRWSBUI) for DBUS_O. In the example configuration, BRWBUSI includes sixteen even BRWBUSIs, namely Even_BRWSBUSI00-Even_BRWSBUSI15, to which the corresponding DBUS_E00-DBUS_E15 are coupled. For example, the set of DBUS_E00<0>-DBUS_E00<7> and DBUSDM_E00 is coupled to Even_BRWSBUSI00, and the set of DBUS_E15<0>-

DBUS_E15<7> and DBUSDM_E15 is coupled to Even_BRWSBUSI15. Likewise, BRWBUSI includes sixteen odd BRWBUSIs, namely Odd_BRWSBUSI00-Odd_BRWSBUSI15, to which the corresponding DBUS_O00-DBUS_O15 are coupled. For example, the set of DBUS_O00<0>-DBUS_O00<7> and DBUSDM_O00 is coupled to Odd_BRWSBUSI00, and the set of DBUS_O15<0>-DBUS_O15<7> and DBUSDM_O15 is coupled to Odd_BRWSBUSI15. For example, if DRAM receives 8 data bits in series, 0, 2, 4 and 6 data bits go through the even data path and 1, 3, 5 and 7 data bits go through the odd data path.

DBUS_E (DBUS_E00-E15) and DBUS_O (DBUS_O00-O15) are then coupled to corresponding even global buses GBUS_E (GBUS_E00-E15) and odd global buses GBUS_O (GBUS_O00-O15) at corresponding Even_BRWSBUSI (Even BRWBUSI00-15) and Odd_BRWSBUSI (Odd_BRWSBUSI00-15), respectively. For example, DBUS_E00<0>-DBUS_E00<7> and DBUSDM_E00 are coupled to GBUS_E00<0>-GBUS_E00<7> and GBUSDM_E00, respectively, at Even_BRWSBUSI00, and DBUS_E15<0>-DBUS_E15<7> and DBUSDM_E15 are coupled to GBUS_E15<0>-GBUS_E15<7> and GBUSDM_E15, respectively, at Even_BRWSBUSI15. Likewise, DBUS_O00<0>-DBUS_O00<7> and DBUSDM_O00 are coupled to GBUS_O00<0>-GBUS_O00<7> and GBUSDM_O00, respectively, at Odd_BRWSBUSI00, and DBUS_O15<0>-DBUS_O15<7> and DBUSDM_O15 are coupled to GBUS_O15<0>-GBUS_O15<7> and GBUSDM_O15, respectively, at Odd_BRWSBUSI15. Even_BRWSBUSIs and Odd_BRWSBUSIs each function as a buffer circuit of data traveling between DBUS_E and GBUS_E and data traveling between DBUS_O and GBUS_O.

GBUS_E (GBUS_E00-E15) and GBUS_O (GBUS_O00-O15) are then coupled to the second buffer BRWBUSIC in GDBuff. BRWBUSIC includes a plurality of BRWBUSICs for corresponding sets of GBUS_E and GBUS_O. In the example configuration, BRWBUSIC includes sixteen BRWBUSICs, namely BRWBUSIC00-BRWBUSIC15. For example, BRWBUSIC00 has the set of GBUS_E00 (<0>-<7> and DM) and GBUS_O00 (<0>-<7> and DM) coupled thereto. BRWBUSIC15 has the set of GBUS_E15 (<0>-<7> and DM) and GBUS_O15 (<0>-<7> and DM) coupled thereto.

Each of BRWBUSICs then consolidates the corresponding set of GBUS_E and GBUS_O into a single set of GBUS. For example, GBUS_E00 (<0>-<7> and DM) and GBUS_O00 (<0>-<7> and DM) are coupled to GBUS_00 (<0>-<7> and DM) at BRWBUSIC00, and GBUS_E15 (<0>-<7> and DM) and GBUS_O15 (<0>-<7> and DM) are coupled to GBUS_15 (<0>-<7> and DM) at BRWBUSIC15. GBUS_00-GBUS_15 are then coupled to an outside component of GDBuff, such as GBuff 203 in FIG. 2. Accordingly, the number of GBUSs that GDBuff processes with the outside component is half of the number of DBUSs that are on the DQ side of GDBuff. As described above, if the total number of DBUSs including the even DBUSs and odd DBUSs between DQs and GDBuff (or between DQ 201 and GDBuff 202 in FIG. 2) is 288, the total number of GBUSs after GDBuff (or between GDBuff 202 and GBuff 203 in FIG. 2) is 144.

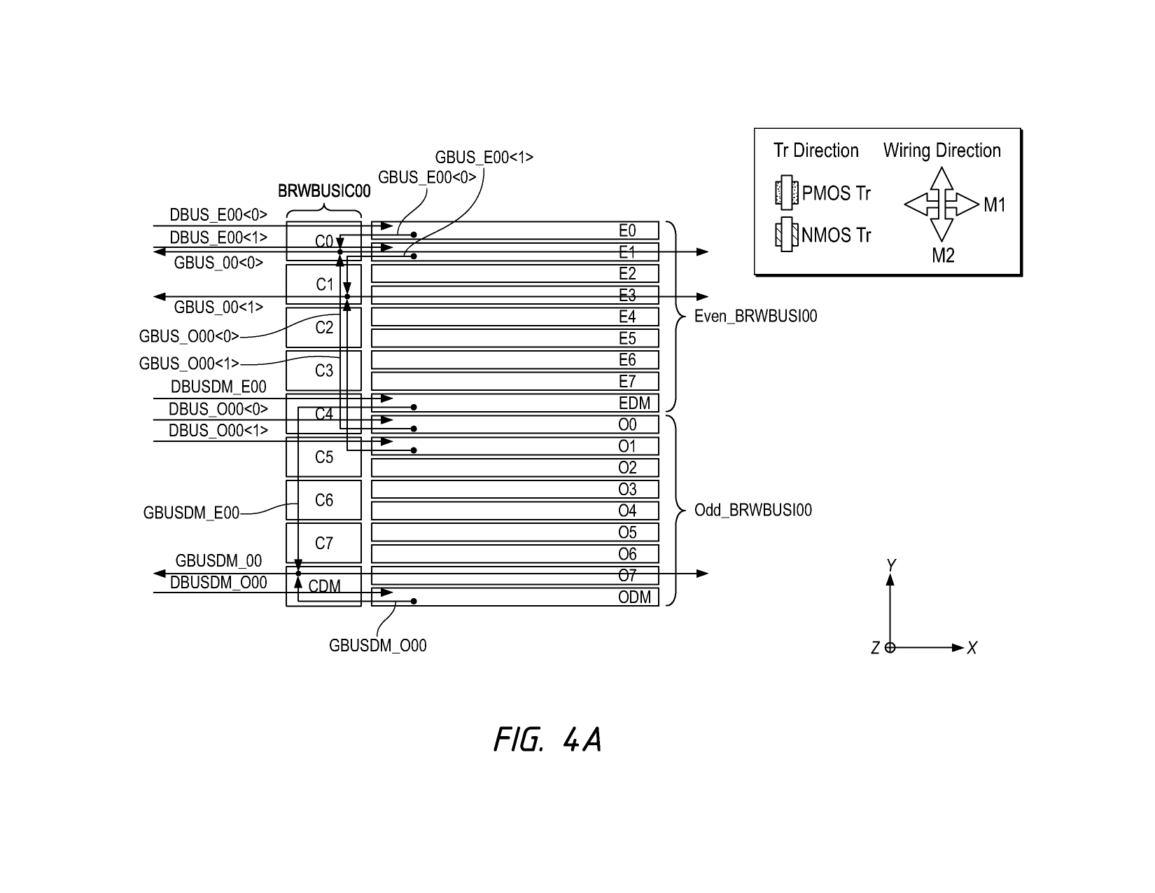

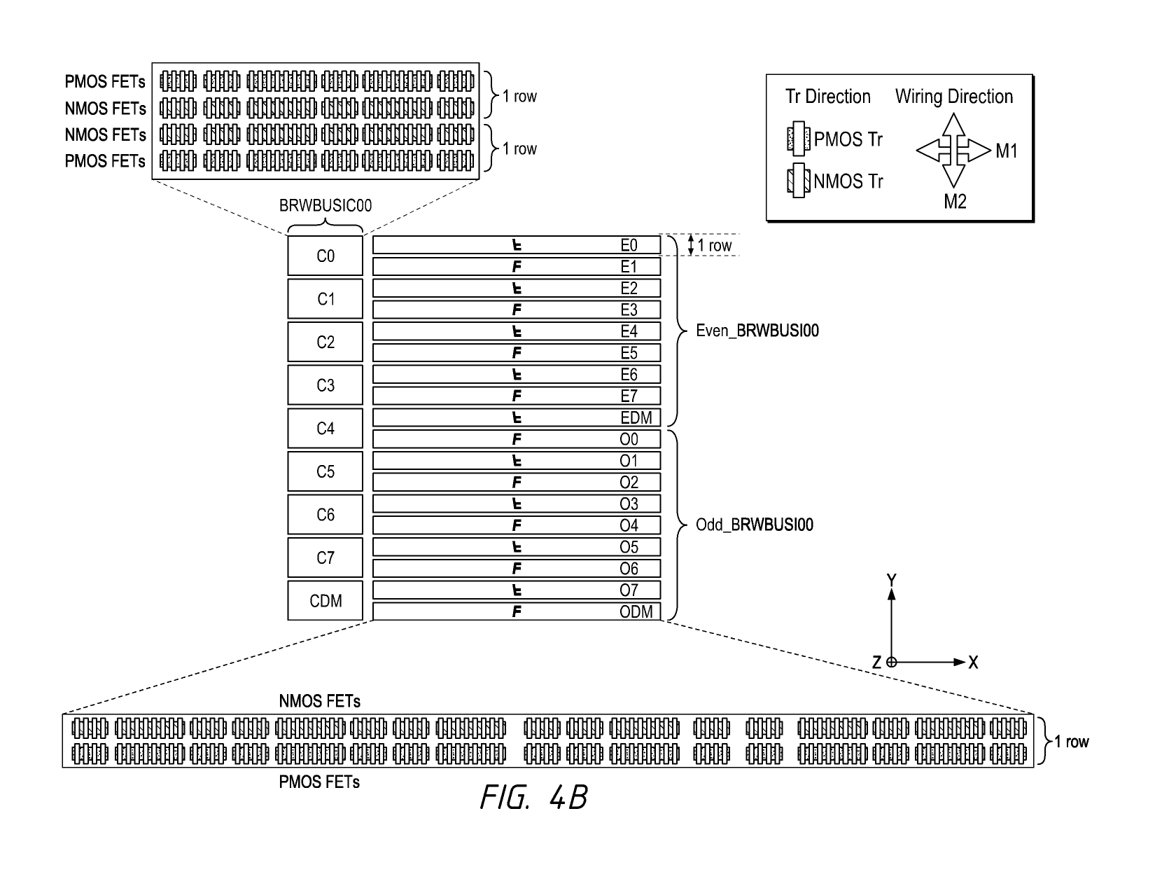

FIGS. 4A and 4B each depict an example layout of a set of BRWBUSIC, Even_BRWBUSI and Odd_BRWBUSI in GDBuff according to some embodiments of the disclosure. BRWBUSIC, Even_BRWBUSI, and Odd_BRWBUSI may correspond to each of BRWBUSIC00-15, Even_BRWBUSI00-15, and Odd_BRWBUSI00-15 in FIG. 3. For ease of description and illustration, BRWBUSIC00, Even_BRWBUSI00, and Odd_BRWBUSI00 are depicted in FIGS. 4A and 4B as one example.

In the example layout, Even_BRWBUSI00 includes a group of even buffers E0, E1, …, E7, EDM (hereinafter referred to as E0-E7 + EDM or E group) corresponding to DQ0-7 + DM. In other words, each of Even_BRWBUSI00-15 includes individual buffers assigned for every one DQ (e.g., E0 for DQ0, E1 for DQ1, and so on). There are nine even buffers in each Even_BRWBUSI for nine DQs. Likewise, Odd_BRWBUSI00 includes a group of odd buffers O0, O1, …, O7, ODM (hereinafter referred to as O0-O7 + ODM or O group) corresponding to DQ0-7 + DM. That is, nine odd buffers in each of Odd_BRWBUSI00-15 are assigned for nine DQs (e.g., O0 for DQ0, O1 for DQ1, and so on). Also, BRWBUSIC00 includes a group of buffers C0, C1, …, C7, CDM (hereinafter referred to as C0-C7 + CDM or C group) for DQ0-7 + DM. The C group is arranged adjacently to the E group and the O group in one horizontal direction in plan view (e.g., an X-axis direction in the drawing; hereinafter referred to as the X-axis direction for ease of description). These groups placed together form one set (which may also be referred to as one buffer cell). There are thus sixteen buffer cells 00-15 in the case of FIG. 3.

As shown in FIGS. 4A and 4B, E0-E7 + EDM are arranged adjacently to and in parallel with one another in another horizontal direction in plan view (e.g., a Y-axis direction in the drawing; hereinafter referred to as the Y-axis direction for ease of description) perpendicular or substantially perpendicular to the X-axis direction. Similarly, O0-O7 + ODM are arranged adjacently to and in parallel with one another in the Y-axis direction. Each of E0-E7 + EDM and

each of O0-O7+ ODM elongates in the X-axis direction, having its length in the X-axis direction longer than that in the Y-axis direction. The E group and the O group are arranged side by side in the Y-axis direction with EDM of the E group and O0 of the O group neighboring each other.

In some instances, the X-axis direction may be the same as a direction of one metal wiring layer (may also be referred to as M1) on a semiconductor substrate, and the Y-axis direction may be the same as a direction of another metal wiring layer (may also be referred to as M2) which may be above or below M1 on the semiconductor substrate. The direction of M1 may be referred to as M1 direction. The direction of M2 may be referred to as M2 direction. As illustrated in FIG. 4B, each of E0-E7 + EDM, O0-O7 + ODM, and C0-C7 + CDM may include one or more buffer circuits, which may include transistors, such as field-effect transistors (FETs). FETs may be complementary metal-oxide-semiconductor (CMOS) transistors each including a p-channel MOS (PMOS) transistor and an n-channel MOS (NMOS) transistor. The PMOS transistor and the NMOS transistor may be aligned with each other in the Y-axis direction. The Y-axis direction may thus be the same as the transistor (Tr) direction. The Tr direction may also be the same as the M2 direction. Each of E0-E7 + EDM and O0-O7 + ODM may have one row of CMOS transistors including one row of PMOS transistors and one row of NMOS transistors adjacent to each other in the Y-axis direction (or Tr/M2 direction). Also, each of C0-C7 + CDM may include one or more buffer circuits each with a similar CMOS transistor arrangement to that of E0-E7 + EDM and O0-O7 + ODM; however, since the C group is shared by the E group and the O group as described in detail below, each of C0-C7 + CDM may include two rows of CMOS transistors assigned for the corresponding even and odd buffers of the E and O groups. For example, first and second rows of CMOS transistors in C0 may be coupled to the CMOS transistor row in E0 and the CMOS transistor row in O0, respectively. First and second rows of CMOS transistors in CDM may be coupled to the CMOS transistor row in EDM and the CMOS transistor row in ODM, respectively.

The C group of BRWBUIC00 is shared by the E group of Even_BRWBUSI00 and the O group of Odd_BRWBUSI00. Each of C0-C7 + CDM is arranged next to a corresponding pair of the neighboring even and odd buffers. For example, C0 is arranged next to the pair of E0 and E1. C1 is arranged next to the pair of E2 and E3. C2 is arranged next to the pair of E4 and E5. C3 is arranged next to the pair of E6 and E7. C4 is arranged next to the pair of EDM and O0. C5 is arranged next to the pair of O1 and O2. C6 is arranged next to the pair of O3 and O4. C7 is arranged next to the pair of O5 and O6. CDM is arranged next to the pair of O7 and ODM.

Each of the even buffers E0-E7 + EDM is coupled to a corresponding even DBUS, and each of the odd buffers O0-O7 + ODM is coupled to a corresponding odd DBUS. For example, E0 is coupled to DBUS_E00<0>, E1 is coupled to DBUS_E00<1>, EDM is coupled to DBUSDM_E00, O0 is coupled to DBUS_O00<0>, O1 is coupled to DBUS_O00<1>, and ODM is coupled to DBUSDM_O00. For ease of description and illustration, the other even and odd DBUSs coupled to the corresponding E and O buffers are not separately depicted in FIG. 4A.

Each of E0-E7 + EDM and each of O0-O7 + ODM are then coupled to corresponding one of C0-C7 + CDM via even GBUS and odd GBUS, respectively. For example, E0 and O0 are coupled to C0 via GBUS_E00<0> and GBUS_O00<0>, respectively. E1 and O1 are coupled to C1 via GBUS_E00<1> and GBUS_O00<1>, respectively. EDM and ODM are coupled to CDM via GBUSDM_E00 and GBUSDM_O00, respectively. As illustrated, GBUS_O00<0> extends to reach C0 from O0, GBUS_O00<1> extends to reach C1 from O1, and GBUSDM_E00 extends to reach CDM from EDM in the Y-axis direction. For ease of description and illustration, the other even and odd GBUSs coupled to the corresponding C buffers are not separately depicted in FIG. 4A.

At each of C0-C7 + CDM, the pair of even GBUS and odd GBUS are coupled to the corresponding single GBUS. For example, at C0, GBUS_E00<0> and GBUS_O00<0> are coupled to the single GBUS_00<0>. At C1, GBUS_E00<1> and GBUS_O00<1> are coupled to the single GBUS_00<1>. At CDM, GBUSDM_E00 and GBUSDM_O00 are coupled to the single GBUSDM_00. The above arrangement also applies to the other C buffers and corresponding even and odd GBUSs although not separately depicted in FIG. 4A.

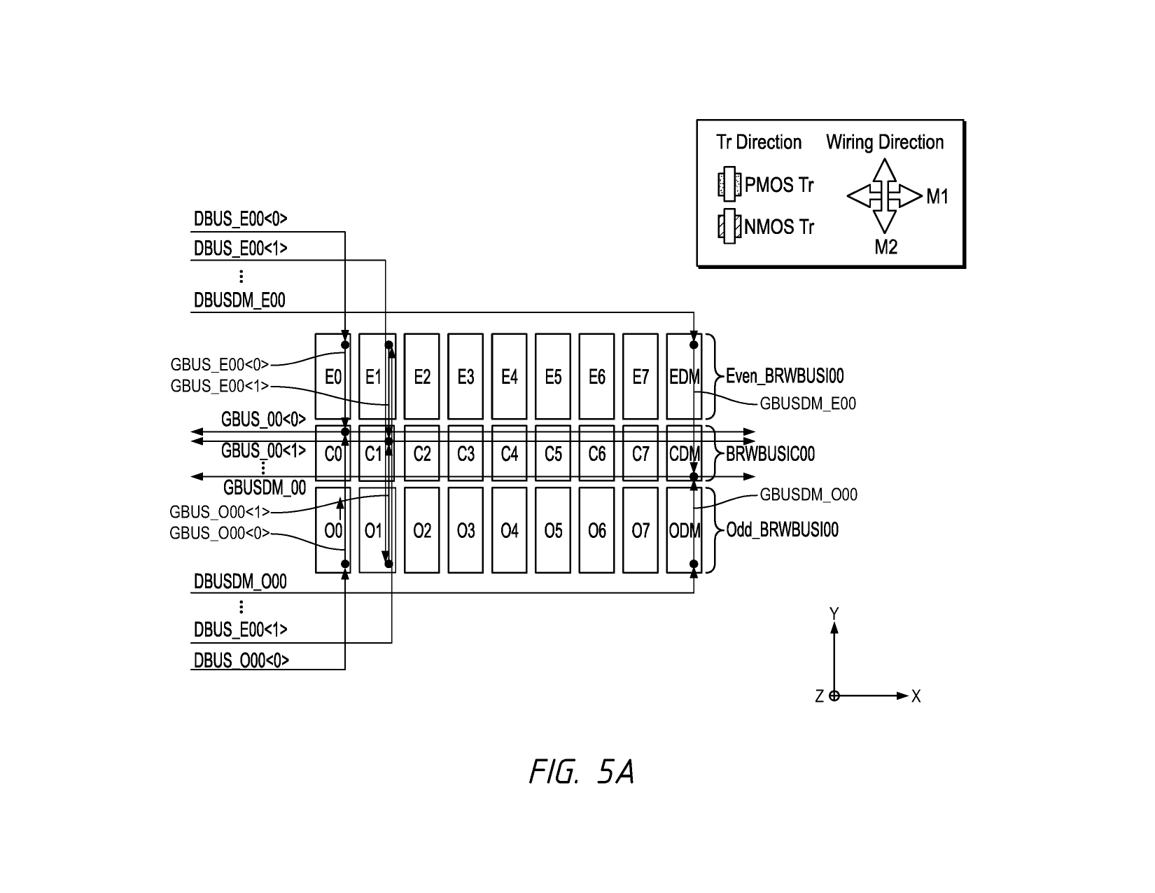

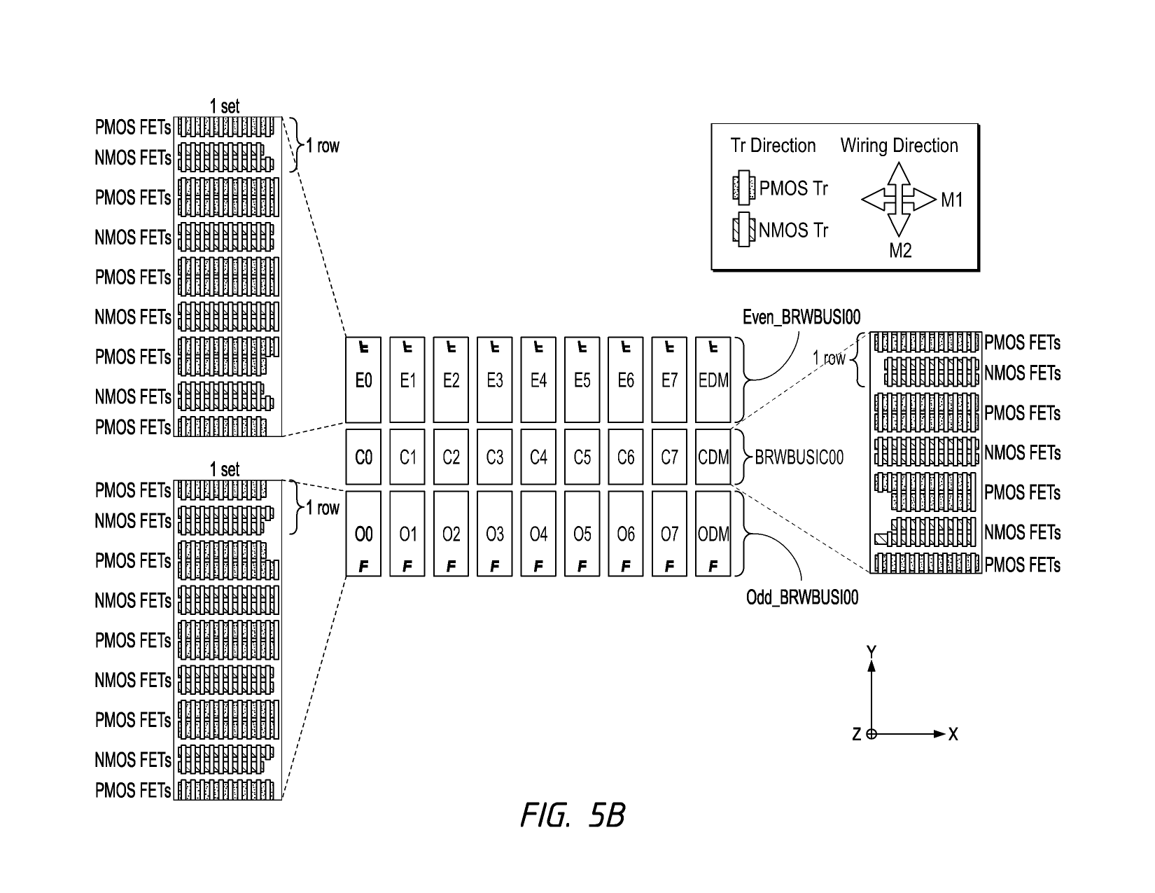

FIGS. 5A and 5B each depict an example layout of a set of BRWBUSIC, Even_BRWBUSI and Odd_BRWBUSI in GDBuff according to some embodiments of the disclosure. Similarly to the example layout of FIGS. 4A and 4B, the example layout of FIGS. 5A and 5B may be applicable to each of BRWBUSIC00-15, Even_BRWBUSI00-15, and Odd_BRWBUSI00-15 in FIG. 3. For ease of description and illustration, BRWBUIC00, Even_BRWBUSI00, and Odd_BRWBUSI00 are depicted in FIG. 5 as one example, which are placed together to form one buffer cell in GDBuff.

The layout of FIGS. 5A and 5B is different from the layout of FIGS. 4A and 4B in that the group of C0-C7 + CDM (or C group) of BWBUSIC00 is provided between the group of E0-E7 + EDM (or E group) of Even_BRWBUSI00 and the group of O0-O7 + ODM (or O group) of Odd-BRWBUSI00. The E group and the O group are arranged at a first position and a second position,

respectively, apart from each other in the Y-axis direction. The C group is arranged at a third position between the E group and the O group in the Y-axis direction. Each of C0-C7 + CDM is sandwiched by the corresponding pair of E0-E7 + EDM and O0-O8 + ODM. For example, C0 is sandwiched by E0 and O0, E1 is sandwiched by E1 and O1, and so on. Accordingly, one BRWBUSIC including individual global buffers assigned for corresponding DQs (e.g., C0 for DQ0, C1 for DQ1, and so on) is sandwiched by the corresponding even and odd BRWBUSIs. Comparing with FIGS. 4A and 4B where E0-E7 + EDM and O0-O8 + ODM elongate in the X-axis direction, E0-E7 + EDM and O0-O8 + ODM in FIGS. 5A and 5B elongate in the Y-axis direction, having the length in the Y-axis direction longer than that in the X-axis direction. As depicted in FIGS. 5A and 5B, the Tr or M2 direction and the M1 direction are the same as those in the layout of FIGS. 4A and 4B.

While in FIG. 4B, each of E0-E7 + EDM and O0-O7 + ODM has one row of CMOS transistors including one row of PMOS transistors and one row of NMOS transistors adjacent to each other in the Y-axis direction, in FIG. 5B, each of E0-E7 + EDM and O0-O7 + ODM has multiple rows of CMOS transistors each including one row of PMOS transistors and one row of NMOS transistors arranged alternately and adjacently to each other in the Y-axis direction. Also, each of C0-C7 + CDM may have a similar CMOS transistor arrangement to that of E0-E7 + EDM and O0-O7 + ODM; however, since the C group is arranged between the E group and the O group, the number of the CMOS transistor rows may be less than that of the E and O groups. As shown in FIG. 4B, one row of CMOS transistors for one DQ extends in the X-axis/M1 direction, and hence a set of nine rows of CMOS transistors corresponding to DQ0-7 + DM for even data and another set of nine rows of CMOS transistors corresponding to DQ0-7 + DM for odd data, that is eighteen rows of CMOS transistors in total for one Even_BRWBUSI and one Odd_BRWBUSI, are arranged in the Y-axis/M2 direction. In the layout of FIG. 4B, hence, an area size in the M2 direction is determined based on how many Even_BRWBUSIs and Odd_BRWBUSIs each including nine CMOS transistor rows are arranged in the M2 direction. In other words, the layout of FIG. 4B may not have much flexibility in the area size in the M2 direction due to the fixed number of CMOS transistor rows in each BRWBUSI. On the other hand, in FIG. 5B, one set of multiple rows (which may be two or more rows) of CMOS transistors for one DQ is provided in the Y-axis/M2 direction, and nine sets of the multiple CMOS transistor rows corresponding to DQ0-7 + DM for even/odd data are arranged in the X-axis/M1 direction. Hence, the layout of FIG. 5B has more flexibility in the area size in the M2 direction than the layout of FIG. 4B. This is particularly advantageous in some instances where there are more spaces in the M2 direction than the M1 direction for read and write data buffer configurations.

Referring to FIG. 5A, each of the even buffers E0-E7 + EDM is coupled to a corresponding even DBUS, and each of the odd buffers O0-O7 + ODM is coupled to a corresponding odd DBUS. For example, E0 is coupled to DBUS_E00<0>, E1 is coupled to DBUS_E00<1>, EDM is coupled to DBUSDM_E00, O0 is coupled to DBUS_O00<0>, O1 is coupled to DBUS_O00<1>, and ODM is coupled to DBUSDM_O00. E0 and O0 are then coupled to C0 via GBUS_E00<0> and GBUS_O00<0>, E1 and O1 are then coupled to C1 via GBUS_E00<1> and GBUS_O00<1>, and EDM and ODM are then coupled to CDM via GBUSDM_E00 and GBUSDM_O00. In other words, for example, DBUS_E00<0> and DBUS_O00<0> are coupled to GBUS_E00<0> and GBUS_O00<0> at E0 and O0, respectively, DBUS_E00<1> and DBUS_O00<1> are coupled to GBUS_E00<1> and GBUS_O00<1> at E1 and O1, respectively, and DBUSDM_E00 and DBUSDM_O00 are coupled to GBUSDM_E00 and GBUSDM_E00 at EDM and ODM, respectively. As illustrated in FIG. 5A, the even GBUS and the odd GBUS (e.g., GBUS_E00<0> and GBUS_O00<0>, GBUS_E00<1> and GBUS_O00<1>, or GBUSDM_E00 and GBUSDM_O00) extend substantially the same distance in the Y-axis direction to reach the corresponding C (e.g., C0 between E0 and O0, C1 between E1 and O1, or CDM between EDM and ODM).

At C0, the pair of GBUS_E00<0> and GBUS_O00<0> are coupled to the single GBUS_00<0>. At C1, the pair of GBUS_E00<1> and GBUS_O00<1> are coupled to the single GBUS_00<1>. At CDM, the pair of GBUSDM_E00 and GBUSDM_O00 are coupled to the single GBUSDM_00. The above configuration also applies to C2-C7 and the corresponding pairs of E2-E7 and O2-O7.

Unlike the example layout of FIGS. 4A and 4B where C0-C7 + CDM in each BRWBUIC are aligned and concentrated in the Y-axis direction (or Tr/M2 direction) and hence the even and odd GBUS wirings for every one DQ may be concentrated in the same or a similar position along the Y-axis direction, since the example layout of FIGS. 5A and 5B is such that E0-E7 + EDM in each Even_BRWBUSI, O0-O7 + ODM in each Odd_BRWBUSI, and C0-C7 + CDM in each BRWBUIC for every one DQ are aligned in the Y-axis direction and spread in the X-axis direction (or M1 direction), the wiring positions of the even and odd GBUSs are more distributed or less condensed than those in the example layout of FIGS. 4A and 4B.

Furthermore, unlike the example layout of FIGS. 4A and 4B where there is a substantive difference in wiring length between the even GBUS and the odd GBUS (e.g., between GBUS_E00<0> and GBUS_O00<0> or between GBUSDM_E00 and GBUSDM_O00), which may require redundancy to make them equal in wiring length, since the example layout of FIGS. 5A and 5B is such that E0-E7 + EDM in each Even_BRWBUSI or O0-O7 + ODM in each Odd_BRWBUSI are placed in the same or substantially the same position relative to C0-C7 + CDM in each BRWBUIC in the Y-axis direction (or Tr/M2 direction), there is no difference or no substantive difference in wiring length between the even GBUS and the odd GBUS such that redundancy is not required for equalizing the even and odd GBUS wiring lengths.

Still furthermore, while the example layout of FIGS. 4A and 4B may lose balance between the even and odd GBUS wirings of one DQ and the even and odd GBUS wirings of another DQ, the example layout of FIGS. 5A and 5B has the aligned arrangement of E0-E7 + EDM in each Even_BRWBUSI, O0-O7 and ODM in each Odd_BRWBUSI, and C0-C7 + CDM in each BRWBUIC for each DQ, and thus the wiring balance between the even and odd GBUS of one DQ and the even and odd GBUS of another DQ can be effectively achieved.

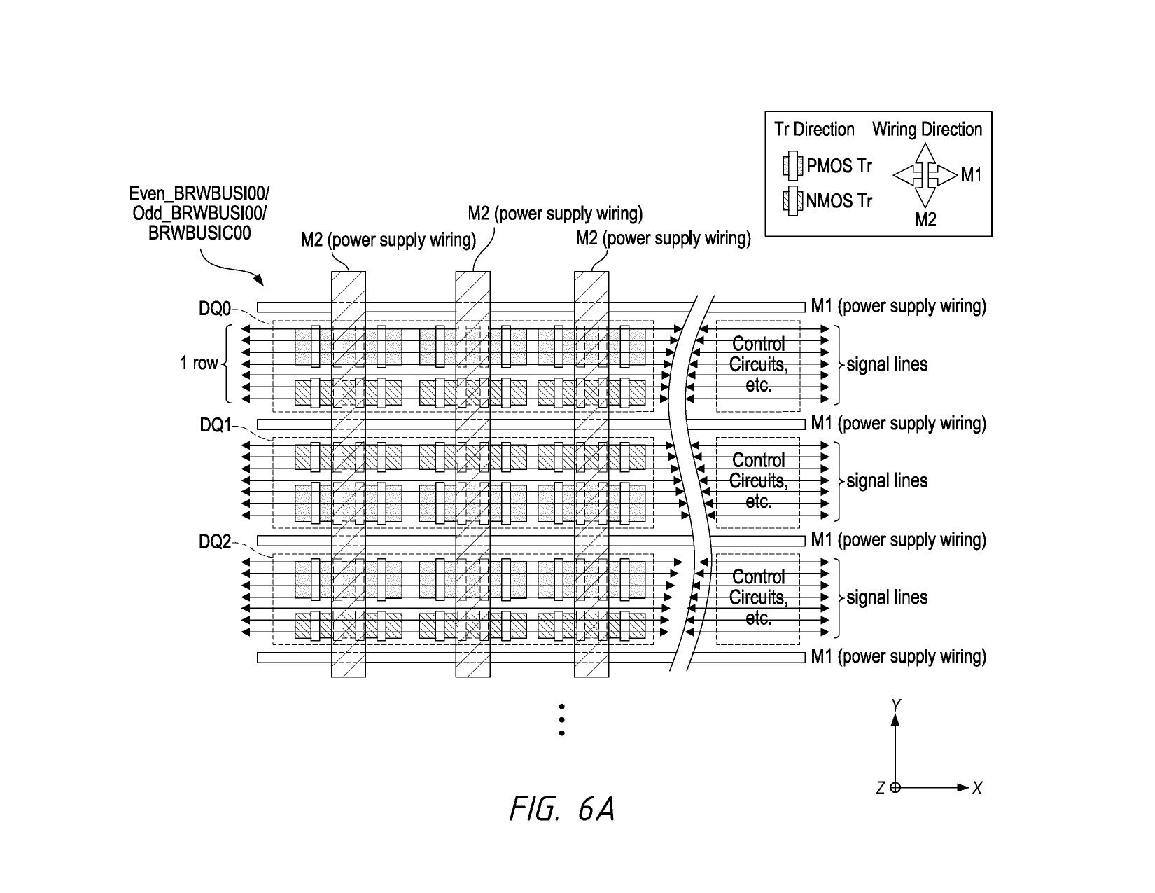

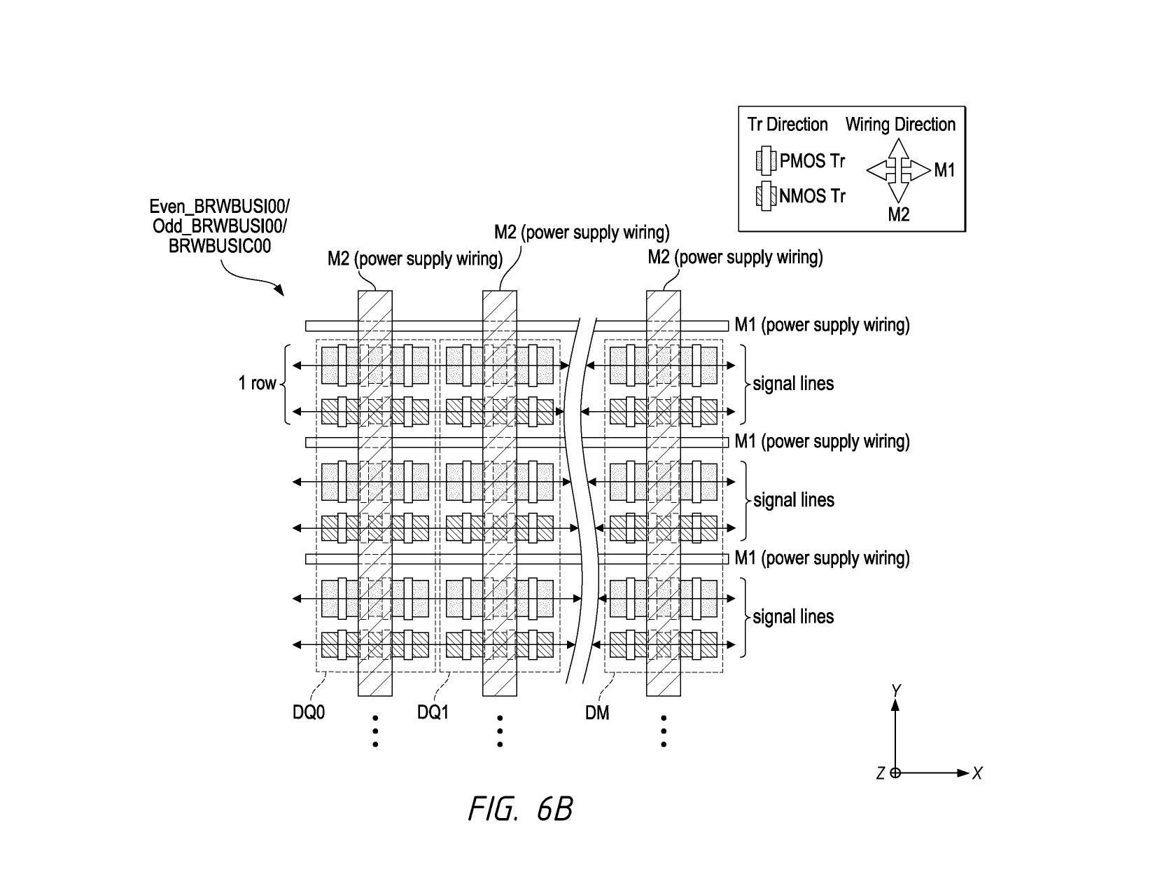

FIGS. 6A and 6B each depict an example arrangement of power supply wirings according to some embodiments of the disclosure. The arrangement of FIG. 6A corresponds to the layout of FIGS. 4A and 4B. The arrangement of FIG. 6B corresponds to the layout of FIGS. 5A and 5B. As shown in FIGS. 4A and 4B, the even buffers E0-E7 + EDM and the odd buffers O0-O7 + ODM for DQ0-7 + DM in each of Even_BRWBUSIs and Odd_BRWBUSIs (Even_BRWBUI00 and Odd_BRWBUSI00 as one example) are aligned in the Y-axis direction, and each of these buffers includes the set of transistors for each DQ in the X-axis direction. As shown in FIG. 6A, power supply wirings to supply power to the buffers are provided in the metal wiring layer M2, extending in the Y-axis direction above the buffers. Other power supply wirings may also be provided in the metal wiring layer M1 extending in the X-axis direction below M2. In the areas next to the buffers in one row, various circuits, such as control circuits, may be provided, and signal lines for the various circuits may be provided in the same layer as M1. Therefore, since there may be little room in the M1 layer to increase the number, the size, and the like of M1, an additional metal layer (not separately depicted) may be needed above M2 in order to enhance the power supply to the buffers.

Turning to FIGS. 5A and 5B and FIG. 6B, the even buffers E0-E7 + EDM and the odd buffers O0-O7 + ODM for DQ0-7 + DM in each of Even_BRWBUSIs and Odd_BRWBUSIs (Even_BRWBUI00 and Odd_BRWBUSI00 as one example) are aligned in the X-axis direction, and each of these buffers includes the set of transistors for each DQ in the Y-axis direction, unlike FIGS. 4A and 4B and FIG. 6A. In this arrangement, while the power to the buffers can be supplied by corresponding M2 , the signal lines provided in the same layer as M1 are mainly for buffer/transistor input and output unlike the signal lines needed for various circuits in the arrangement of FIG. 6A. Therefore, since the M1 layer in FIG. 6B has more room than the M1 layer in FIG. 6A, the M1 layer can be used (for example, the number, the size, and the like of M1 can be increased) for enhancement of the power supply to the buffers without using an additional metal layer above M2. The same or substantially the same goes for BRWBUSIC.

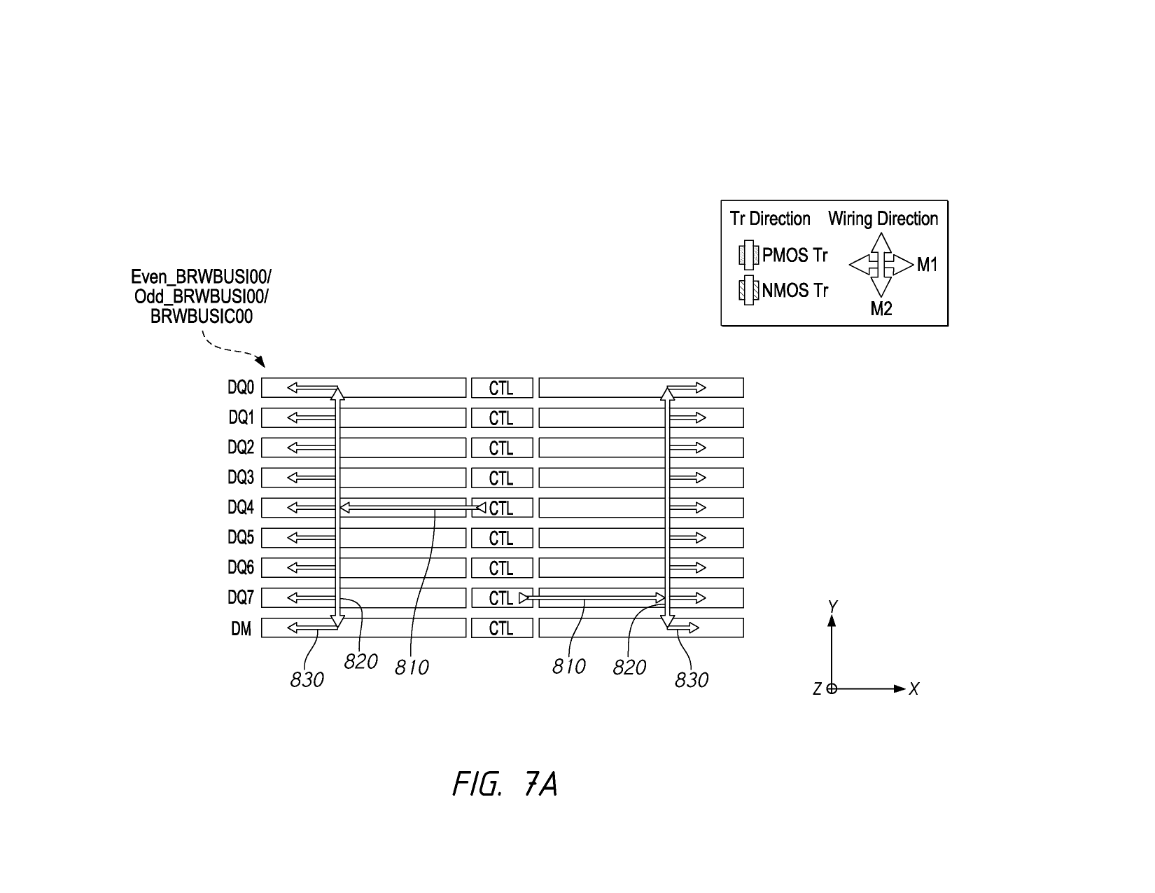

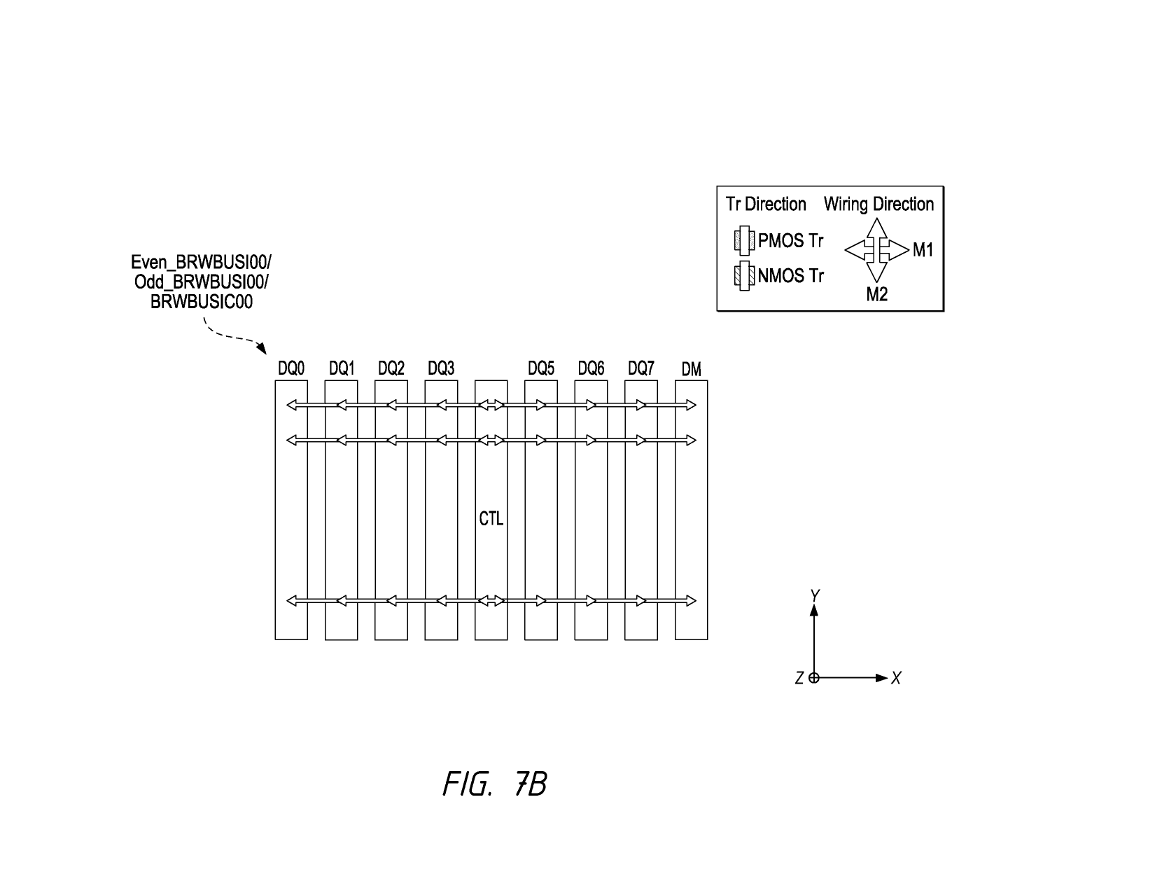

FIGS. 7A and 7B each depict an example arrangement of control circuits and signal lines according to some embodiments of the disclosure. The arrangement of FIG. 7A corresponds to the layout of FIGS. 4A and 4B. The arrangement of FIG. 7B corresponds to the layout of FIGS. 5A and 5B. As shown in FIG. 7A, there may be control circuits CTL of the buffers for DQ0-7 + DM in each of Even_BRWBUSIs and Odd_BRWBUSIs (Even_BRWBUI00 and Odd_BRWBUSI00 as one example). Each of the control circuits CTL may be coupled to the buffers via a first signal line 810 extending from the control circuit CTL in the X-axis direction in the M1 layer, a second signal line 820 extending in the Y-axis direction in the M2 layer, and a plurality of third signal lines 830 extending from the second signal line 820 to the corresponding buffers in the X-axis direction in the M1 layer. This way, various signals, such as control signals, from the control circuit CTL are distributed to the buffers in each BRWBUSI. Turning to FIG. 7B, all signal lines can be arranged extending in the X-axis direction in the M1 layer without using the M2 layer. This effectively achieves simpler and shorter signal line path using only the M1 layer than the case of FIG. 7A which requires both M1 and M2 layers for signal line path. The same or substantially the same goes for BRWBUSIC.

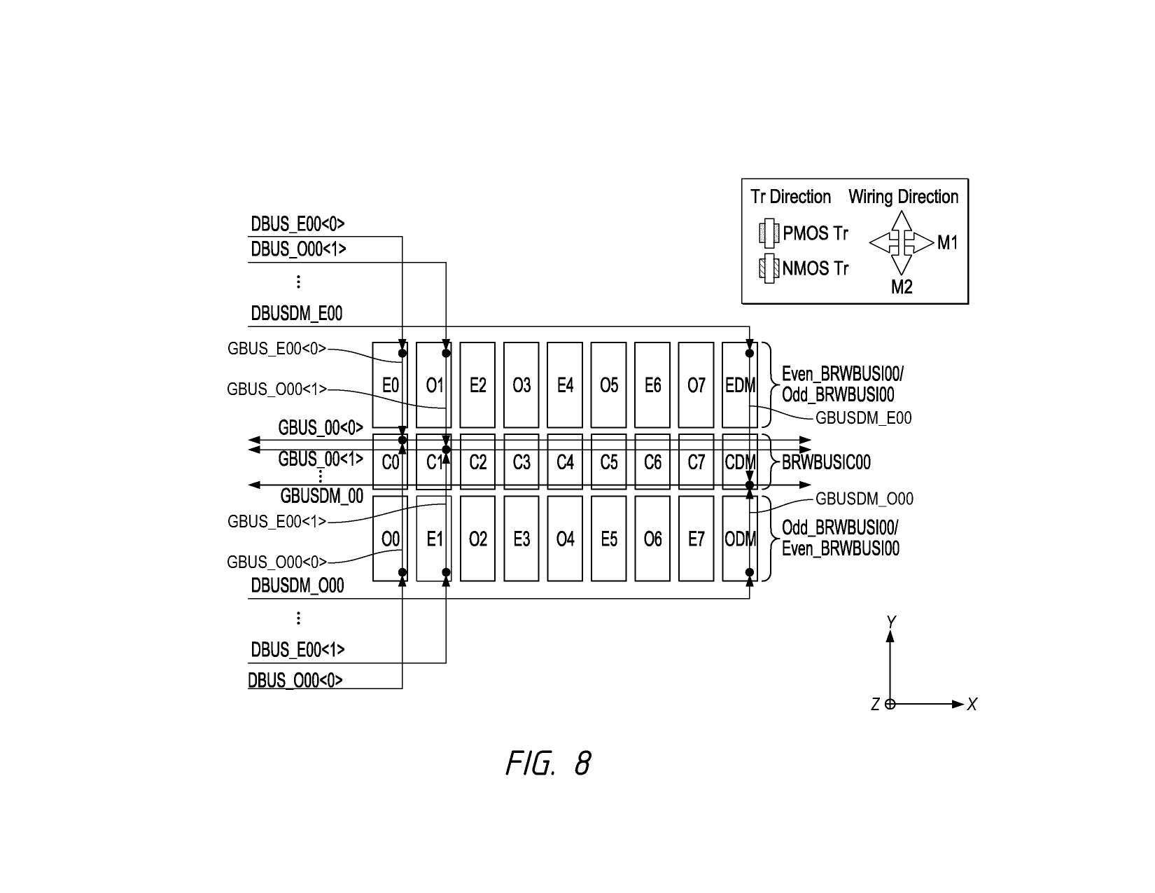

FIG. 8 depicts an example layout of a set of BRWBUSIC, Even_BRWBUSI and Odd_BRWBUSI in GDBuff according to some embodiments of the disclosure. While in the layout of FIG. 5A, the even buffers E0-E7 + EDM of each of Even_BRWBUSIs and the odd buffers O0-O7 + ODM of each of Odd_BRWBUSIs are arranged as one E group and one O group, respectively, in the layout of FIG. 8, E0-E7 + EDM and O0-O7 + ODM are alternately arranged in the X-axis direction, forming a first half-E and half-O hybrid group and a second half-E and half-O hybrid group that sandwich the C group in the Y-axis direction. When the buffers operate, the even buffers may operate simultaneously and the odd buffers may operate simultaneously, but the even buffers and the odd buffers may not operate at the same time. Therefore, in the layout of FIG. 5A, there are nine buffers (E0-E7 + EDM or O0-O7 + ODM that operate at the same time with the power supply from M1. On the other hand, there are only four or five buffers (E0, E2, E4, E6, and EDM or O1, O3, O5, and O7 in the first half-E and half-O hybrid group or E1, E3, E5, and E7 or O0, O2, O4, O6, and ODM in the second half-E and half-O hybrid group) that operate at the same time with the power supply from M1. Compared with the layout of FIG. 5, hence, the layout of FIG. 8 reduces the buffer operation current which flows through M1 by half or substantially half. Also, in the layout of FIG. 8, since the even buffers and the odd buffers are alternately wired, the variation in length of lead-in wirings of even and odd DBUSs extending in the Y-axis direction is reduced in comparison with that in the layout of FIG. 5A. For example, in FIG. 5A, DBUS_E00<1> has its lead-in wiring extending over O1 and C1 and then reaching E1 on the other side in the Y-axis direction whereas in FIG. 8, the lead-in wiring of DBUS_E00<1> reaches directly to E1. In FIG. 5A, DBUS_O00<1> has its lead-in wiring extending over E1 and C1 and then reaching O1 whereas in FIG. 8, the lead-in wiring of DBUS_O00<1> reaches directly to O1. The same goes for the other even and odd DBUSs. Therefore, the layout of FIG. 8 has the lead-in wiring arrangement of DBUSs simplified from the layout of FIG. 5.

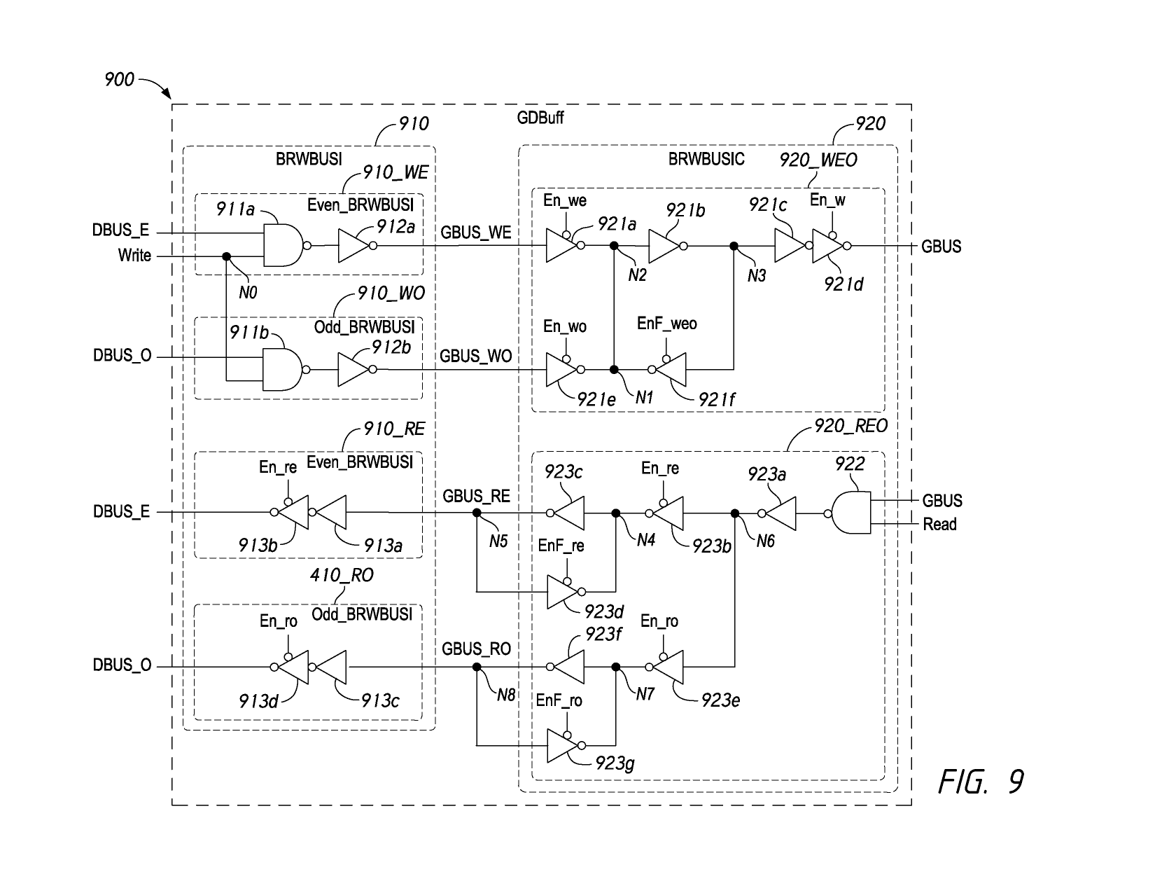

FIG. 9 is a schematic diagram of at least part of an example buffer circuit 900 according to some embodiments of the disclosure. The example buffer circuit 900 includes a first buffer circuit 910 (may also be referred to as BRWBUSI) and a second buffer circuit 920 (may also be referred to as BRWBUSIC). The first buffer circuit 910 includes an even buffer circuit Even_BRWBUSI and an odd buffer circuit Odd_BRWBUSI. Even_BRWBUSI and Odd-BRWBUSI of the first buffer circuit 910 are coupled to data terminals, such as DQ in FIGS. 1-3, via even data buses DBUS_E and odd data buses DBUS_O, respectively. The second buffer circuit 920 is coupled to Even_BRWBUSI and Odd-BRWBUSI via an even global data bus GBUS_E and an odd global data bus GBUS_O, respectively. The second buffer circuit 920 consolidates the even global data bus GBUS_E and the odd global data bus GBUS_O into a single global data bus GBUS. The term “coupled” herein may include “connected.”

The first buffer circuit 910 and the second buffer circuit 920 may be included in the global data bus-data bus buffer GDBuff in FIG. 3. The even buffer circuit Even BRWBUSI and the odd buffer circuit Odd-BRWBUSI of the first buffer circuit 910 may be applicable to each of Even_BRWBUSI00-15and each of Odd_BRWSBUSI00-15 in FIG. 3, respectively. The second buffer circuit 920 may be applicable to each of BRWBUSIC00-15in FIG. 3. The even data bus DBUS_E and the odd data bus DBUS_O may correspond to each of DBUS_E00-E15 and each of DBUS_O00-O15 in FIG. 3, respectively. The even global data bus GBUS_E and the odd global data bus GBUS_O may correspond to each of GBUS_ E00-E15and each of GBUS_O00-O15 in FIG. 3, respectively. The global data bus GBUS may correspond to each of GBUS_00-15 in FIG. 3. GBUS may be coupled to GBuff 203 in FIG. 2.

The example buffer circuit 900 includes a write data path and a read data path separately. Even_BRWBUSI of the first buffer circuit 910 includes a write even buffer 910_WE and a read even buffer 910_RE. Odd-BRWBUSI of the first buffer circuit 910 includes a write odd buffer 910_WO and a read odd buffer 910_RO. The second buffer circuit 920 includes a write buffer 920_WEO and a read buffer 920_REO. The write even buffer 910_WE, the write odd buffer 910_WO, and the write buffer 920_WEO are configured for data write operation. The read even buffer 910_WR, the read even buffer 910_RO, and the read buffer 920_REO are configured for data read operation.

In the first buffer circuit 910/BRWBUSI, the write even buffer 910_WE, that is an even buffer for data write operation, includes a logic NAND gate 911a on an input side and a logic NOT gate (or inverter) 912a on an output side. A first input terminal of the NAND gate 911a is coupled to DBUS_E to receive even write data from one or more data terminals. A second input terminal of the NAND gate 911a is coupled to one or more internal terminals (indicated as “Write” in the drawing) to receive an internal write command. The internal write command (hereinafter also referred to as Write) may be generated from a write command supplied from external devices. An output terminal of the NAND gate 911a is coupled to an input terminal of the inverter 912a. An output terminal of the inverter 912a is coupled to GBUS_E for data write operation (GBUS_WE). The write odd buffer 910_WO, that is an odd buffer for data write operation, has a similar logic gate structure including series-coupled NAND gate 911b and inverter 912b, except that a first input terminal of the NAND gate 911b is coupled to DBUS_O to receive odd write data and a second input terminal is commonly coupled to the internal terminal Write with the second input terminal of the NAND gate 911a of the write even buffer 910_WE at a node N0. An output terminal of the inverter 912b is coupled to GBUS_O for data write operation (GBUS_WO).

In the second buffer circuit 920/BRWBUSIC, the write buffer 920_WEO includes, for the even data path of write operation, series-coupled multiple inverters 921a-d that are coupled to GBUS_WE at an input terminal of the first inverter 921a and coupled to GBUS at an output terminal of the last inverter 921d. The write buffer 920_WEO includes, for the odd data path of write operation, an inverter 921e and an inverter 921f with output terminals thereof coupled to each other at a node N1. The node N1 is coupled to a node N2 between the output terminal of the inverter 921a and the input terminal of the inverter 912b. The inverter 921e includes an input terminal coupled to GBUS_WO, and the inverter 921f includes an input terminal coupled to the input terminal of the inverter 921b at a node N3. The inverters 921b and 921f may constitute a latch circuit. The inverters 921a, 921d, 921e, and 921f may be clocked inverters, and may be activated by enable pulse signals En_we, En_w, and En_wo, and an inverse enable pulse signal EnF_weo, respectively, which may be generated based on or in response to the write command.

When the internal write command Write is in a High state during the write operation, the NAND gate 911a and the NAND gate 911b are enabled, and the even data and the odd data from DBUS_E and DBUS_O flow through the write even buffer 910_WE and the write odd buffer 910_WO and are passed to the write buffer 920_WEO via GBUS_WE and GBUS_WO, respectively. In the write buffer 920_WEO, during the even data write operation, the inverter 921a is turned on/open in response to En_we (whereas the inverter 921e is closed), and the even data is latched at the inverters 921b and 921f and passed to GBUS through the inverters 921c and 921d. During the odd data write operation, the inverter 921e is turned on/open in response to En_wo (whereas the inverter 921a is closed), and the odd data is latched at the inverters 921b and 921f and passed to GBUS through the inverters 921c and 921d. With the above configuration, the write buffer 920_WEO of the second buffer circuit 920 is shared by the write even buffer 910_WE and the write odd buffer 910_WO of the first buffer circuit 910 for the data write operation. The even global data bus GBUS_WE from the write even buffer 910_WE and the odd global data bus GBUS_WO from the write odd buffer 910_WO reach the write buffer 920_WEO and are coupled to the single global data bus GBUS for the data write operation.

Still referring to FIG. 9, and turning to data read operation, the second buffer circuit 920/BRWBUSIC receives read data from GBUS and transmits, via GBUS_E and GBUS_O for data read operation (GBUS_RE and GBUS_RO), the read date to the first buffer circuit 910/BRWBUSI, which then sends the read data to the data terminals via DBUS_E and DBUS_O. In the second buffer circuit 920, the read buffer 920_REO includes a logic NAND gate 922 on an input side and a plurality of logic NOT gates or inverters 923a-c coupled in series to each other and to the NAND gate 922. A first input terminal of the NAND gate 922 is coupled to GBUS to receive the read data from, for example, GBuff 203 in FIG. 2. A second input terminal of the NAND gate 922 is coupled to one or more internal terminals (indicated as “Read” in the drawing) to receive an internal read command. The internal read command (hereinafter also referred to as Read) may be generated from a read command supplied from external devices. An output terminal of the NAND gate 922 is coupled to an input terminal of the first inverter 923a of the inverters 923a-c. An output terminal of the first inverter 923a is coupled to an input terminal of the second inverter 923b. An output terminal of the second inverter 923b is coupled to an input terminal of the third inverter 923c. An output terminal of the third inverter 923c is coupled to GBUS_RE. At the third inverter 923c, another inverter 923d is provided with its output terminal coupled to a node N4 between the output terminal of the second inverter 923b and the input terminal of the third inverter 923c. The inverter 923d includes an input terminal coupled to the output terminal of the inverter 923c at a node N5 which is coupled to GBUS_RE. The inverters 923c and 923d may constitute a latch circuit for even read data. The inverters 923b and 923d may be clocked inverters, and may be activated by an enable pulse signal En_re and an inverse enable pulse signal EnF_re, respectively, which may be generated based on or in response to the read command. The above configuration is designed for the even data path of read operation.

The read buffer 920_REO of the second buffer circuit 920 further includes another inverter 923e coupled to the output terminal of the first inverter 923a at a node N6, and still another inverter 923f coupled in series with the inverter 923f at a node N7. An output terminal of the inverter 923f is coupled to GBUS_RO. Similarly to the parallel-coupled inverters 923c and 923d on the even data path, another inverter 923g is provided with its output and input terminals coupled to the input and output terminals of the inverter 923f at nodes N7 and N8, respectively. The inverters 923f and 923g may constitute a latch circuit for odd read data. The inverters 923e and 921g may be clocked inverters, and may be activated by an enable pulse signals En_ro and an inverse enable pulse signal EnF_ro, respectively, which may be generated based on or in response to the read command. The above configuration forms the odd data path of read operation.

In the first buffer circuit 910, the read even buffer 910_RE includes, for the even data read operation, inverters 913a and 913b coupled in series with each other. An input terminal of the inverter 913a is coupled to GBUS_RE, and an output terminal of the inverter 913b is coupled to DBUS_E. Similarly, the read odd buffer 910_RO further includes, for the odd data read operation, series-coupled inverters 913c and 913d with an input terminal of the inverter 913c coupled to GBSU_RO and an output terminal of the inverter 913d coupled to DBUS_O. The inverters 913b and 913d may be clocked inverters, and may be activated by enable pulse signals En_re and En_ro, which may be generated based on or in response to the read command.

When the internal read command Read is in a High state during the read operation, the NAND gate 922 is enabled, and the even read data and the odd read data from GBUS enter into the read buffer 920_REO and are passed to the read even buffer 910_RE and the read odd buffer 910_RO via GBUS_RE and GBUS_RO, respectively. In the read buffer 920_REO, during the even data read operation, the inverter 923b is turned on/open in response to En_re (whereas the inverter 923e is closed), and the even data is latched at the inverters 923c and 923d and passed to GBUS_RE. During the odd data write operation, the inverter 923e is turned on/open in response to En_ro (whereas the inverter 923b is closed), and the odd data is latched at the inverters 923f and 923g and passed to GBUS_RO. At the read even buffer 910_RE and the read odd buffer 910_RO, the even data and the odd data are passed to DBUS_E and DBUS_O through the inverters 913a and 913b (when open in response to En_re) and the inverters 913c and 913d (when open in response to En_ro), respectively. With the above configuration, the read buffer 920_REO of the second buffer circuit 920 is shared by the read even buffer 910_RE and the read odd buffer 910_RO of the first buffer circuit 910 for the data read operation. The single global data bus GBUS is coupled to the even global data bus GBUS_RE and the odd global data bus GBUS_RO for the data read operation.

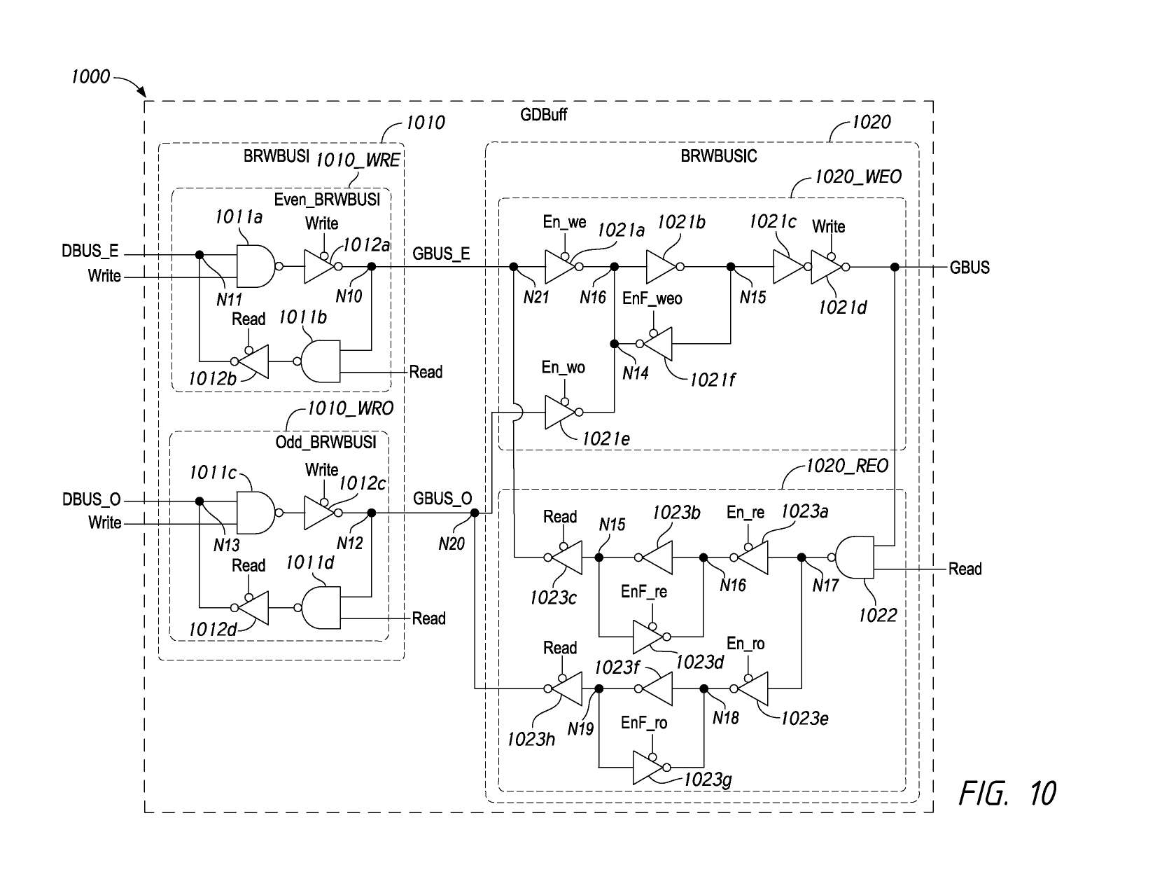

FIG. 10 is a schematic diagram of at least part of an example buffer circuit 1000 according to some embodiments of the disclosure. The example buffer circuit 1000 includes a first buffer circuit 1010 (may also be referred to as BRWBUSI) and a second buffer circuit 1020 (may also be referred to as BRWBUSIC). The first buffer circuit 1010 includes an even buffer circuit Even_BRWBUSI and an odd buffer circuit Odd_BRWBUSI. Even_BRWBUSI and Odd-BRWBUSI of the first buffer circuit 1010 are coupled to data terminals, such as DQ in FIGS. 1-3, via even data buses DBUS_E and odd data buses DBUS_O, respectively. The second buffer circuit 1020 is coupled to Even_BRWBUSI and Odd-BRWBUSI via an even global data bus GBUS_E and an odd global data bus GBUS_O, respectively. The second buffer circuit 1020 consolidates the even global data bus GBUS_E and the odd global data bus GBUS_O into a single global data bus GBUS. The term “coupled” herein may include “connected.”

Similarly to the buffer circuit 900, the first buffer circuit 1010 and the second buffer circuit 1020 may be included in the global data bus-data bus buffer GDBuff in FIG. 3. Even BRWBUSI and Odd-BRWBUSI of the first buffer circuit 1010 may be applicable to each of Even_BRWBUSI00-15and each of Odd_BRWSBUSI00-15 in FIG. 3, respectively. The second buffer circuit 920 may be applicable to each of BRWBUSIC00-15in FIG. 3. DBUS_E and DBUS_O may correspond to each of DBUS_E00-E15 and each of DBUS_O00-O15 in FIG. 3, respectively. GBUS_E and GBUS_O may correspond to each of GBUS_ E00-E15and each of GBUS_O00-O15in FIG. 3, respectively. GBUS may correspond to each of GBUS_00-15 in FIG. 3. GBUS may be coupled to GBuff 203 in FIG. 2.

The buffer circuit 1000 is different from the buffer circuit 900 at least in that Even_BRWBUSI and Odd_BRWBUSI of the first buffer circuit 1010 do not have separate blocks for the write operation and the read operation. Corresponding to the configuration of the first buffer circuit 1010, the second buffer circuit 1020/BRWBUSIC is adjusted.

In the first buffer circuit 1010/BRWBUSI, Even_BRWBUSI and Odd_BRWBUSI include a write and read even buffer 1010_WRE and a write and read odd buffer 1010_WRO, respectively. The write and read even buffer 1010_WRE includes a first set of series-coupled logic NAND gate 1011a and inverter 1012a and a second set of series-coupled logic NAND gate 1011b and inverter 1012b. The first set of the NAND gate 1011a and inverter 1012a is configured for even data write operation and has the same or substantially the same configuration (the detailed descriptions of which are omitted herein) as the write even buffer 910_WE of BRWBUSI/910 in the buffer circuit 900, except that the inverter 1012a operates in response to the internal write command Write, which is also input to the second input terminal of the NAND gate 1011a, to operate and output the even write data only during the write operation. The second set of the NAND gate 1011b and inverter 1012b is configured for even data read operation and is coupled in parallel to and in an inverse manner to the first set. A first input terminal of the NAND gate 1011b is coupled to GBUS_E at a node N10 (which is also coupled to an output terminal of the inverter 1012a) to receive the even read data, and a second input terminal thereof is coupled to one or more internal terminals to receive the internal read command. An output terminal of the NAND gate 1011b is coupled to an input terminal of the inverter 1012b, which is enabled by the internal read command, to operate and output the even read data only during the read operation. An output terminal of the inverter 1012b is commonly coupled to DBUS_E with the first input terminal of the NAND gate 1011a at a node N11. With this configuration constituting the even data path, during the write operation, the even write data is input from DBUS_E to the NAND gate 1011a and output to GBUS_E from the inverter 1012a in response to the internal write command Write. During the read operation, the even read data is input to the NAND gate 1011b from GBUS_E (that is from the second buffer circuit 1020 along the read data path, which will be described in detail below) and output to DBUS_E from the inverter 1012b in response to the internal read command Read. For the odd data path, the write and read odd buffer 1010_WRO includes a first set of series-coupled logic NAND gate 1011c and inverter 1012c and a second set of series-coupled logic NAND gate 1011d and inverter 1012d with the same or substantially the same configuration (the descriptions of which are omitted herein) as the write and read even buffer 1010_WRE, except that a first input terminal of the NAND gate 1011c is coupled to DBSU_O to receive the odd write data and that a first input terminal of the NAND gate 1011d is coupled to GBUS_O at a node N12 (which is also coupled to an output terminal of the inverter 1012c) to receive the odd read data from the second buffer circuit 1020 along the read data path.

Turning to the BRWBUSIC side, the second buffer circuit 1020 includes a write buffer 1020_WEO for the even and odd data write operation and a read buffer 1020_REO for the even and odd data read operation. The write buffer 1020_WEO includes inverters 1021a-f and nodes N14-16 having the same or substantially the same configuration (the detailed descriptions of which are omitted herein) as the write buffer 920_WEO of BRWBUSI/920 in the buffer circuit 900, except that the inverter 1021a on the even data path is coupled to GBUS_E and the inverter 1021e on the odd data path is coupled to GBUS_O. Also, while the inverters 1021a-f substantially correspond to the inverters 921a-f, respectively, the inverter 1021d on the output side operates in response to the internal write command Write unlike the inverter 921d which operates in response to the enable pulse signal En_w. The inverter 1021d is open during the write operation while it is closed during the read operation so that the read data from GBUS does not travel on the write data path but travels to the NAND gate 1022 on the read data path. The nodes N14-16 correspond to the nodes N1-3, respectively. With this configuration, during the write operation, the even write data and the odd write data are passed from GBUS_E to the single GBUS along the even data path and the odd data path, respectively, in the write buffer 1020_WEO.

For the even and odd data read operation, the read buffer 1020_REO is different from the read buffer 920_REO of BRWBUSI/920 in the buffer circuit 900 in that, firstly, on the even data path, a first inverter 1023a and a third inverter 1023c are clocked inverters that operate in response to the enable pulse signal En_re and the internal read command Read, respectively, and a latch circuit is provided at a second inverter 1023b with an inverter 1023d coupled in parallel to and in an inverse manner to the inverter 1023b at nodes N15 and N16. Secondly, on the odd data path that is split from the even data path at a node N17 on the output side of the NAND gate 1022, the read buffer 1020_REO includes an inverter 1023h on the output side which operates in response to the internal read command Read and is coupled to GBUS_O at a node N20 to output the odd read data. Inverters 1023e-g correspond to the inverters 923e-f of the read buffer 920_REO, respectively, with the latch circuit including the inverters 1023f and 1023g at nodes N18 and N19 between the inverter 1023e and the inverter 1023h. With this configuration, during the read operation, the even read data is input from GBUS to the NAND gate 1022 and output to GBUS_E from the inverter 1023c at a node N21 in response to the internal read command Read and the corresponding enable signals for the even data inverters on the even data path, and the odd read data is also input from GBUS to the NAND gate 1022 and output to GBUS_O from the inverter 1023h at the node N20 in response to the internal read command Read and the corresponding enable signals for the odd data inverters on the odd data path.

In the above embodiments, one example of the apparatus 100 or 200 may be a DRAM. However, a DRAM is merely one example, and the embodiments and the descriptions herein are not intended to be limited to a DRAM. Memory devices other than a DRAM, such as a static random-access memory (SRAM), a flash memory, an erasable programmable read-only memory (EPROM), a magnetoresistive random-access memory (MRAM), and a phase-change memory, can also be applied as the apparatus described herein. Furthermore, devices other than memory devices, including logic ICs, such as a microprocessor and an application-specific integrated circuit (ASIC), are also applicable as the apparatus described herein according to the present embodiments.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still fall within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. An apparatus, comprising:
a data terminal;
a first buffer coupled to the data terminal; and
a second buffer coupled to the first buffer, wherein
the first buffer includes an even buffer and an odd buffer coupled to the data terminal via an even data bus and an odd data bus, respectively,
the second buffer is coupled to the even buffer and the odd buffer of the first buffer via an even global data bus and an odd global data bus, respectively, and is configured to consolidate the even global data bus and the odd global data bus into a single global data bus.

2. The apparatus according to claim 1, wherein
the even buffer and the odd buffer of the first buffer each extend in a first direction and are adjacent to each other in a second direction perpendicular to the first direction, and
the second buffer is adjacent to the even buffer and the odd buffer in the first direction.

3. The apparatus according to claim 2, wherein the second buffer is shared by the even buffer and the odd buffer of the first buffer.

4. The apparatus according to claim 2, wherein the even global data bus from the even buffer of the first buffer and the odd global data bus from the odd buffer of the first buffer reach the second buffer and are coupled to the single global data bus at the second buffer.

5. The apparatus according to claim 2, wherein each of the even buffer and the odd buffer includes a PMOS transistor and a NMOS transistor arranged adjacently to each other in the second direction.

6. The apparatus according to claim 2, wherein each of the even buffer and the odd buffer includes a first row of PMOS transistors in the first direction and a second row of NMOS transistors in the first direction, and the first row and the second row are adjacent to each other in the second direction.

7. The apparatus according to claim 1, wherein the second buffer is arranged between the even buffer and the odd buffer of the first buffer.

8. The apparatus according to claim 7, wherein the second buffer is shared by the even buffer and the odd buffer of the first buffer.

9. The apparatus according to claim 7, wherein the even global data bus from the even buffer of the first buffer and the odd global data bus from the odd buffer of the first buffer reach the second buffer and are coupled to the single global data bus at the second buffer.

10. The apparatus according to claim 7, wherein each of the even buffer and the odd buffer includes a PMOS transistor and a NMOS transistor arranged adjacently to each other in a direction same as a direction of the arrangement of the second buffer between the even buffer and the odd buffer of the first buffer.

11. The apparatus according to claim 7, wherein each of the even buffer and the odd buffer includes a plurality of first rows of PMOS transistors in a first direction and a plurality of second rows of NMOS transistors in the first direction, and the plurality of first rows and the plurality of second rows are alternately arranged in a second direction perpendicular to the first direction.

12. The apparatus according to claim 1, wherein the data terminal provides data to and from a memory device.

13. An apparatus, comprising:
a data terminal;
a first buffer coupled to the data terminal; and
a second buffer coupled to the first buffer, wherein
the first buffer includes an even buffer and an odd buffer coupled to the data terminal via an even data bus and an odd data bus, respectively,
the second buffer is coupled to the even buffer and the odd buffer of the first buffer via an even global data bus and an odd global data bus, respectively, and is configured to consolidate the even global data bus and the odd global data bus into a single global data bus, and
the second buffer is sandwiched by the even buffer and the odd buffer of the first buffer.

14. The apparatus according to claim 13, wherein the even global data bus from the even buffer of the first buffer and the odd global data bus from the odd buffer of the first buffer reach the second buffer and are coupled to the single global data bus at the second buffer.

15. The apparatus according to claim 13, wherein each of the even buffer and the odd buffer includes a plurality of first rows of PMOS transistors in a first direction and a plurality of second rows of NMOS transistors in the first direction, and the plurality of first rows and the plurality of second rows are alternately arranged in a second direction perpendicular to the first direction.

16. An apparatus, comprising:
a plurality of data terminals;
a plurality of first even buffers, each of the first even buffers coupled to the plurality of data terminals via a plurality of even data buses;
a plurality of first odd buffers, each of the first even buffers coupled to the plurality of data terminals via a plurality of odd data buses; and
a plurality of second buffers, each of the second buffers coupled to a corresponding pair of a first even buffer and a first odd buffer among the plurality of first even buffers and the plurality of first odd buffers via a plurality of even global data buses and a plurality of odd global data buses, each of the second buffers also coupled to a plurality of single global data buses, wherein
a pair of an even global data bus and an odd global data bus among the plurality of even global data buses and the plurality of odd global data buses are coupled to a corresponding single global data bus among the plurality of single global data buses at a corresponding second buffer among the plurality of second buffers.

17. The apparatus according to claim 16, wherein
the plurality of first even buffers form a group of the first even buffers, each of the first even buffers extending in a first direction, the plurality of first odd buffers form a group of the first odd buffers, each of the second even buffers extending in the first direction,
the group of the first even buffers and the group of the first even buffers are adjacent to each other in a second direction perpendicular to the first direction, and
the plurality of second buffers form a group of the second buffers adjacent to the group of the first even buffers and the group of the first odd buffers in the first direction, and
the pair of the even global data bus and the odd global data bus from the first even buffer and the first odd buffer reach the corresponding second buffer and are coupled to the corresponding single global data bus at the corresponding second buffer.

18. The apparatus according to claim 17, wherein each of the first even buffers and the first odd buffers includes a first row of PMOS transistors in the first direction and a second row of NMOS transistors in the first direction, and the first row and the second row are adjacent to each other in the second direction.

19. The apparatus according to claim 16, wherein
the plurality of first even buffers form a group of the first even buffers,
the plurality of first odd buffers form a group of the second even buffers,
the group of the first even buffers and the group of the second even buffers are adjacent to each other, and
the plurality of second buffers form a group of the second buffers between the group of the first even buffers and the group of the first odd buffers.

20. The apparatus according to claim 19, wherein each of the first even buffers and the first odd buffers includes a plurality of first rows of PMOS transistors in a first direction and a plurality of second rows of NMOS transistors in the first direction, and the plurality of first rows and the plurality of second rows are alternately arranged in a second direction perpendicular to the first direction.
